(19) United States
(12) Patent Application Publication
(10) Pub. No.: US 2025/0309164 A1
(43) Pub. Date: Oct. 2, 2025

(54) BONDED ASSEMBLY OF MEMORY AND LOGIC DIE HAVING DIFFERENT BONDING PAD SIZE AND METHODS FOR FORMING THE SAME

(71) Applicant: SANDISK TECHNOLOGIES LLC, ADDISON, TX (US)

(72) Inventors: Mitsuteru MUSHIGA, Yokkaichi (JP); Fen YANG, Yokkaichi (JP); Tsuyoshi TANIMOTO, Yokkaichi (JP)

(21) Appl. No.: 18/618,434

(22) Filed: Mar. 27, 2024

(51) Int. Cl. H01L 23/00; H01L 23/48; H01L 25/00; H01L 25/18

(52) U.S. Cl. CPC H01L 24/08; H01L 23/481; H01L 24/05; H01L 24/80; H01L 25/18; H01L 25/50; H10B 80/00; H01L 2224/05647; H01L 2224/0603; H01L 2224/0616; H01L 2224/08145; H01L 2224/80011; H01L 2224/80013; H01L 2224/80019; H01L 2224/80194; H01L 2224/80895; H01L 2924/1431; H01L 2924/1434; H10B 41/27; H10B 43/27; H10B 51/20

(57) ABSTRACT

A semiconductor structure includes a memory die including memory-side bonding pads. The memory-side bonding pads include first-type memory-side bonding pads electrically connected to a respective one of word lines or bit lines, and second-type memory-side bonding pads electrically connected to a source layer. Each of the first-type memory-side bonding pads has a first bonding surface area, and each of the second-type memory-side bonding pads has a second bonding surface area greater than the first bonding surface area.

### FIELD

The present disclosure relates generally to the field of semiconductor devices, and particularly to a bonded assembly of logic and memory die having different bonding pad size and methods for forming the same.

### BACKGROUND

A pair of semiconductor dies may be bonded to each other to form a semiconductor chip. Metal-to-metal bonding may be employed to provide signal paths between the pair of semiconductor dies.

### SUMMARY

According to an aspect of the present disclosure, a semiconductor structure comprising a memory die is provided. The memory die comprises: source layer; an alternating stack of insulating layers and electrically conductive layers; memory openings vertically extending through the alternating stack; memory opening fill structures located in the memory openings, wherein each of the memory opening fill structures comprises a respective vertical semiconductor channel, a respective vertical stack of memory elements located at levels of the electrically conductive layers, and a respective drain region contacting a first end of the respective vertical semiconductor channel, wherein a second end of the respective vertical semiconductor channel is electrically connected to the source layer, and wherein the electrically conductive layers comprise word lines of the respective vertical stack of memory elements; bit lines electrically connected to a respective subset of the drain regions; and memory-side dielectric material layers embedding memory-side metal interconnect structures and memory-side bonding pads, wherein the memory-side bonding pads comprise first-type memory-side bonding pads electrically connected to a respective one of the word lines and the bit lines, and comprise second-type memory-side bonding pads electrically connected to the source layer, wherein each of the first-type memory-side bonding pads has a first bonding surface area, and each of the second-type memory-side bonding pads has a second bonding surface area that is larger than the first bonding surface area.

According to another aspect of the present disclosure, a method of forming a semiconductor structure is provided. The method comprises: providing memory die comprising an alternating stack of insulating layers and electrically conductive layers, memory openings vertically extending through the alternating stack, memory opening fill structures located in the memory openings, wherein each of the memory opening fill structures comprises a respective vertical semiconductor channel, a respective vertical stack of memory elements located at levels of the electrically conductive layers, a respective drain region contacting a first end of the respective vertical semiconductor channel, a source layer electrically connected to second ends of a respective subset of the vertical semiconductor channels, wherein the electrically conductive layers comprise word lines of the respective vertical stack of memory elements, bit lines electrically connected to a respective subset of the drain regions, memory-side dielectric material layers embedding memory-side metal interconnect structures and memory-side bonding pads, wherein the memory-side bonding pads comprise first-type memory-side bonding pads electrically connected to a respective one of the word lines or the bit lines, and second-type memory-side bonding pads electrically connected to the source layer, wherein each of the first-type memory-side bonding pads has a first bonding surface area, and each of the second-type memory-side bonding pads has a second bonding surface area that is larger than the first bonding surface area; plasma treating the memory side bonding pads; chemically cleaning the memory side bonding pads; and bonding the memory die to a logic die.

### BRIEF DESCRIPTION OF THE DRAWINGS

FIG. 1 is a vertical cross-sectional view of an exemplary structure after formation of a stopper insulating layer, in-process source-level material layers, a first-tier alternating stack, and a first-tier stepped dielectric material portion according to an embodiment of the present disclosure.

FIG. 2A is a vertical cross-sectional view of the exemplary structure after formation of first-tier memory openings and first-tier support openings according to an embodiment of the present disclosure.

FIG. 2B is a top-down view of the exemplary structure of FIG. 2A. The hinged vertical plane A-A′ is the cut plane of the vertical cross-sectional view of FIG. 2A.

FIG. 3 is a vertical cross-sectional view of the exemplary structure after formation of first sacrificial opening fill structures according to an embodiment of the present disclosure.

FIG. 4 is a vertical cross-sectional view of the exemplary structure after formation of a second-tier alternating stack, a second-tier stepped dielectric material portion, second-tier memory openings, second-tier support openings, and second sacrificial opening fill structures according to an embodiment of the present disclosure.

FIG. 5 is a vertical cross-sectional view of the exemplary structure after formation of support pillar structures according to an embodiment of the present disclosure.

FIG. 6 is a vertical cross-sectional view of the exemplary structure after formation of inter-tier memory openings according to an embodiment of the present disclosure.

FIGS. 7A-7E are sequential vertical cross-sectional views of a memory opening during formation of a memory opening fill structure according to an embodiments of the present disclosure.

FIG. 8A is a schematic vertical cross-sectional view of the exemplary structure after formation of memory opening fill structures according to an embodiment of the present disclosure.

FIG. 8B is a top-down view of the exemplary structure of FIG. 8A. The vertical plane A-A is the cut plane of the vertical cross-sectional view of FIG. 8A.

FIG. 9A is a vertical cross-sectional view of the exemplary structure after formation of lateral isolation trenches according to an embodiment of the present disclosure.

FIG. 9B is a top-down view of the exemplary structure of FIG. 9A. The vertical plane A-A is the cut plane of the vertical cross-sectional view of FIG. 9A.

FIGS. 10A-10D are sequential vertical cross-sectional views of the exemplary structure during replacement of the in-process source-level material layers with a source layer according to an embodiment of the present disclosure.

FIG. 11 is a vertical cross-sectional view of the exemplary structure after formation of laterally-extending cavities according to an embodiment of the present disclosure.

FIG. 12 is a schematic vertical cross-sectional view of the exemplary structure after formation of electrically conductive layers according to an embodiment of the present disclosure.

FIG. 13A is a vertical cross-sectional view of the exemplary structure after formation of lateral isolation trench fill structures, layer contact via structures, and drain contact via structures according to an embodiment of the present disclosure.

FIG. 13B is a top-down view of the exemplary structure of FIG. 13A. The vertical plane A-A is the cut plane of the vertical cross-sectional view of FIG. 13A.

FIG. 14A is a vertical cross-sectional view of the exemplary structure after formation of connection via structures and bit lines according to an embodiment of the present disclosure.

FIG. 14B is a top-down view of a region of the exemplary structure of FIG. 14A.

FIG. 15A is a vertical cross-sectional view of the exemplary structure after formation of memory-side dielectric material layers embedding memory-side metal interconnect structures and memory-side bonding pads to provide a memory die according to an embodiment of the present disclosure.

FIG. 15B is a top-down view of a region of the exemplary structure of FIG. 15A.

FIG. 16A is a vertical cross-sectional view of a logic die according to an embodiment of the present disclosure.

FIG. 16B is a top-down view of a region of the logic die of FIG. 16A.

FIG. 17 is a vertical cross-sectional view of the exemplary structure after attaching the logic die to the memory die according to an embodiment of the present disclosure.

FIG. 18 is a vertical cross-sectional view of the exemplary structure after removal of the carrier substrate according to an embodiment of the present disclosure.

FIG. 19 is a vertical cross-sectional view of the exemplary structure after formation of backside contact pads according to an embodiment of the present disclosure.

### DETAILED DESCRIPTION

As discussed above, the embodiments of the present disclosure are directed to a bonded assembly of logic and memory die containing bonding pads of different size and methods for forming the same, the various aspects of which are described below. Embodiments of the disclosure can be employed to form various semiconductor structures such as a bonded assembly of a memory die and a logic die.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Prior to bonding two dies to each other or bonding two wafers containing respective dies to each other using opposing copper bonding pads, the surfaces of the copper bonding pads may be pre-treated by a plasma treatment process to enhance the bonding characteristics of the bonding pads. The surfaces of the dies or wafers may be cleaned with a cleaning solution after the plasma treatment but before bonding the bonding pads to each other.

Without wishing to be bound by a particular theory, the present inventors believe that the copper bonding pads become charged during the plasma treatment process. Then during the subsequent chemical cleaning process, the charged copper ions (e.g., Cu²⁺ ions) from the bonding pads are dissolved into the cleaning solution and may be precipitated from the cleaning solution on other surfaces of the dies, such as on surfaces of the same bonding pads. The copper dissolution causes pits (e.g., recesses and/or voids) in the bonding pads, while the copper precipitation causes copper protrusions (e.g., bumps) on the die surfaces, such as on the same or other copper bonding pad surfaces. The copper protrusions form an uneven surface, which is similar to a non-uniform surface caused by metal corrosion. The voids and protrusions degrade the quality of the bonding, which may lead to open or short circuits between the opposing dies.

The present inventors realized that by including bonding pads of different size, the copper dissolution and/or precipitation may be reduced or avoided, which improves the quality of the bonding between opposing bonding pads. Embodiments of the present disclosure provide bonded assembly of two dies, such as a memory die containing three-dimensional memory devices and a logic die containing a peripheral circuit for controlling operation of the three-dimensional memory device. The memory-side bonding pads of the memory die and the logic-side bonding pads of the logic die are configured to mitigate the pits and protrusions caused by copper dissolution and precipitation (i.e., redeposition). Specifically, the size of the bonding pads is varied among different types of bonding pads provide a more uniform bonding pad surface. The bonding pads may comprise first-type, second-type, and third-type memory-side bonding pads, each designed with different surface areas and functional roles to combat these adverse effects. The memory-side bonding pads may comprise first-type memory-side bonding pads having a medium size, second-type memory-side bonding pads having a larger size to reduce the height of the protrusions, and third-type memory-side bonding pads having a smaller size to minimize the amount of pits. Similarly, the logic-side bonding pads may comprise first-type logic-side bonding pads having the medium size, second-type logic-side bonding pads having the larger size, and third-type logic-side bonding pads having the smaller size, which are bonded to opposing memory bonding pads having the same relative size.

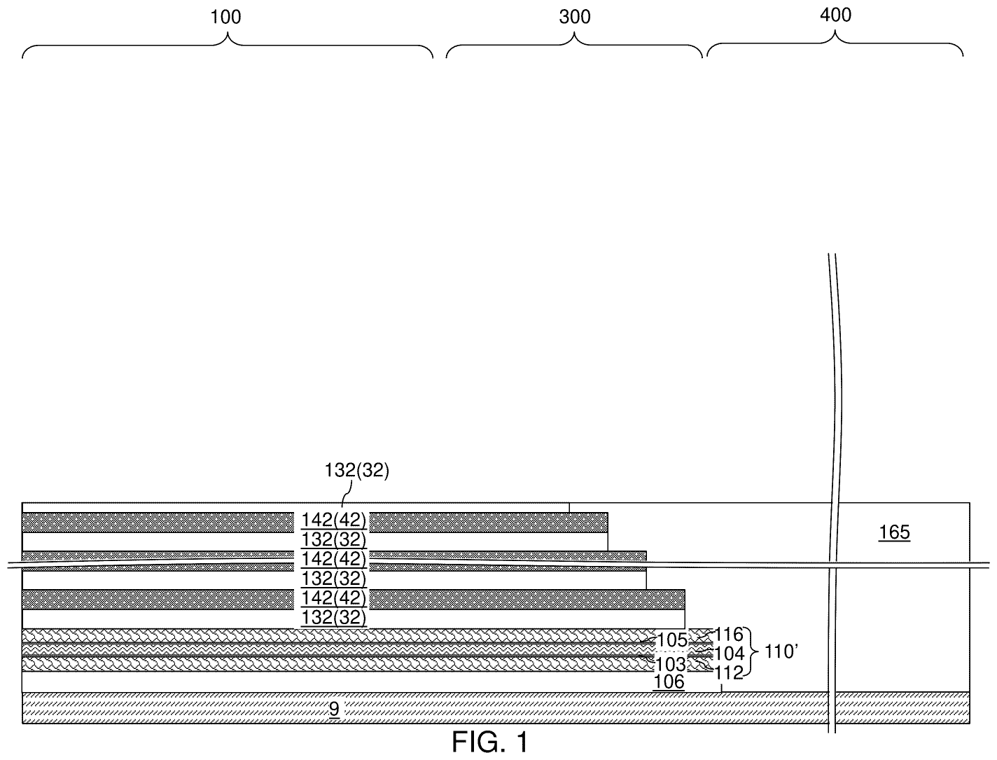

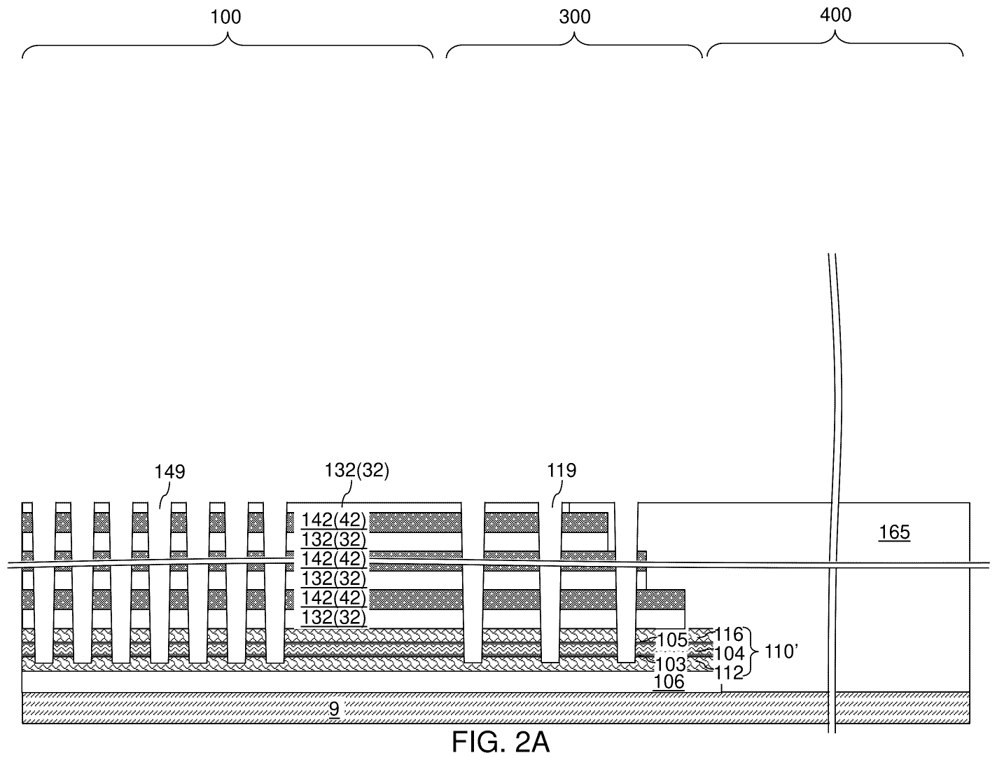

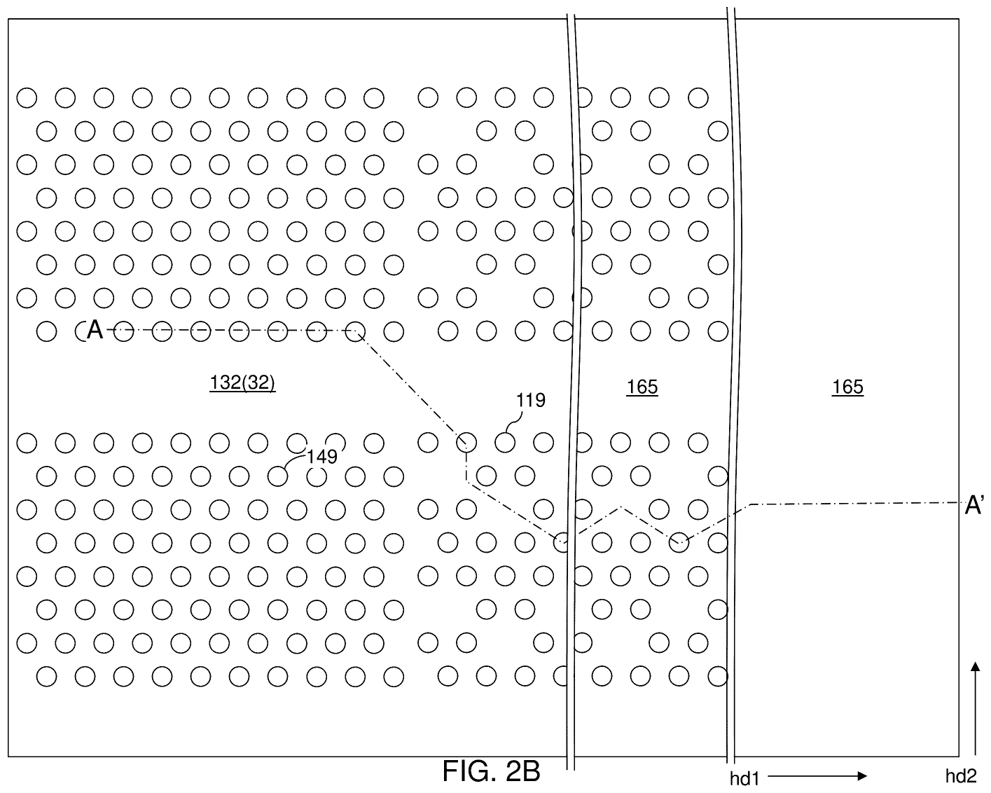

Referring to FIG. 1, an exemplary structure according to a first embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective to the material of a stopper insulating layer 106, which is formed on a top surface of the carrier substrate 9.

An insulating material layer can be formed on a top surface of the carrier substrate The insulating material layer can be subsequently employed as a stopping material layer for a process that removes the carrier substrate 9, and is herein referred to as a stopper insulating layer 106, or as a backside pad dielectric layer. If a polishing process such as a chemical mechanical polishing process is employed to subsequently remove the carrier substrate 9, the stopper insulating layer 106 may be subsequently employed as a polishing stopper material layer. If an etch process such as a wet etch process is employed to subsequently remove the carrier substrate 9, the stopper insulating layer 106 may be subsequently employed as an etch stop material layer. In one embodiment, the stopper insulating layer 106 comprises a dielectric material such as undoped silicate glass, a doped silicate glass, or silicon nitride. The thickness of the stopper insulating layer 106 may be in a range from 100 nm to 1,000 nm, such as from 200 nm to 600 nm, although lesser and greater thicknesses may also be employed.

In-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

A first alternating stack of insulating layers 32 and spacer material layers can be formed over the in-process source-level material layers 110′. The spacer material layers may be formed as sacrificial material layers 42. In case a second alternating stack of additional insulating layers and additional spacer material layers is subsequently formed over the first alternating stack to form a multi-tier structure, the first alternating stack is referred to as a first-tier alternating stack, and the second alternating stack is referred to as a second-tier alternating stack. In this case, the insulating layers 32 within the first-tier alternating stack are herein referred to as first insulating layers 132, and spacer material layers (such as the sacrificial material layers 42) within the first-tier alternating stack are herein referred to as first spacer material layers (such as first sacrificial material layers 142).

The first insulating layers 132 comprise an insulating material such as undoped silicate glass or a doped silicate glass, and the first sacrificial material layers 142 comprise a sacrificial material such as silicon nitride or a silicon-germanium alloy. In one embodiment, the first insulating layers 132 may comprise silicon oxide layers, and the first sacrificial material layers 142 may comprise silicon nitride layers. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. The exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. In this case, processing steps performed to replace the first sacrificial material layers 142 with first electrically conductive layers may be omitted. Generally, spacer material layers may be formed as or may be subsequently replaced with electrically conductive layers.

Optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the stepped surfaces. A “stepped cavity” refers to a cavity having stepped surfaces.

The first stepped cavity can have various stepped surfaces such that the horizontal cross-sectional shape of the first stepped cavity changes in steps as a function of the vertical distance from the top surface of the carrier substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the alternating stack (132, 142) laterally extends farther than any overlying first sacrificial material layer 142 within the first-tier alternating stack (132, 142) in the terrace region. The stepped surfaces of the first-tier alternating stack (132, 142) continuously extend from a bottommost layer within the first-tier alternating stack (132, 142) to a topmost layer within the first-tier alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the stepped cavity. Excess portions of the deposited dielectric material can be removed from above the top surface of the topmost layer of the first-tier alternating stack (132, 142), for example, by chemical mechanical planarization (CMP). The remaining portion of the deposited dielectric material filling the first stepped cavity constitutes the first stepped dielectric material portion 165. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F.

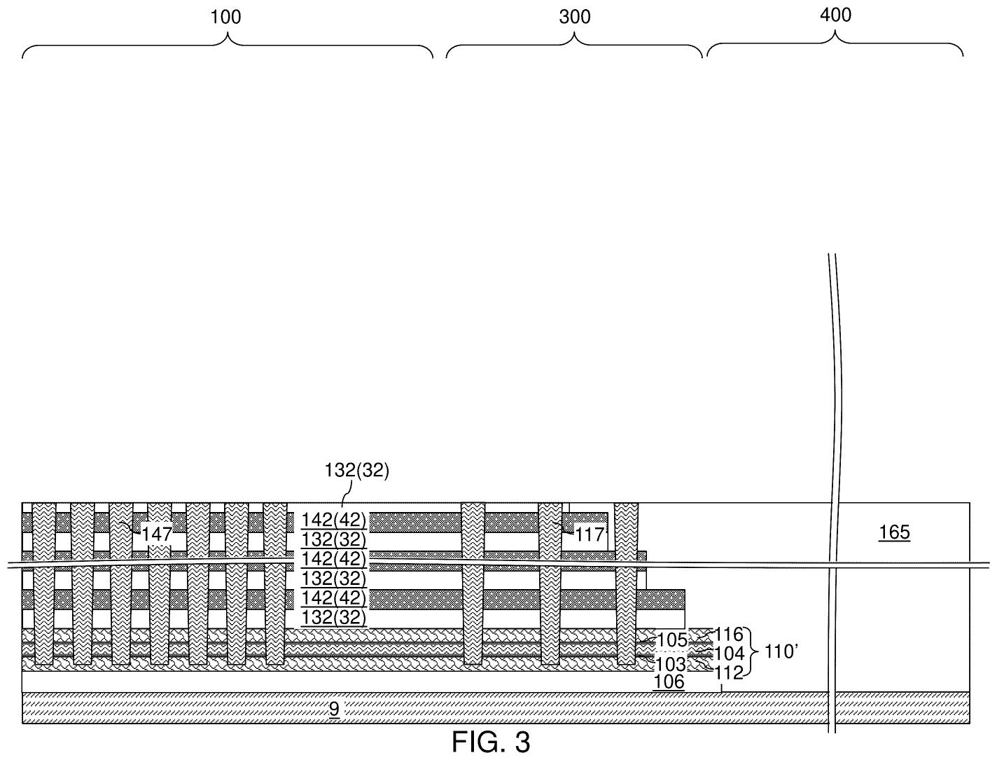

Referring to FIG. 3, a first etch mask layer (such as a photoresist layer) can be formed over the first-tier alternating stack (132, 142), and can be lithographically patterned to form openings therein. A first anisotropic etch process can be performed to transfer the pattern of the openings in the first etch mask layer through the first stepped dielectric material portion 165, and the first-tier alternating stack (132, 142), and into the in-process source-level material layers 110′. First-tier memory openings 149 can be formed through the first-tier alternating stack (132, 142) in the memory array region 100, and first-tier support openings 119 can be formed through the first stepped dielectric material portion 165 and the first-tier alternating stack (132, 142) in the contact region 300. Each of the first-tier memory openings 149 and the first-tier support openings 119 can vertically extend into the in-process source-level material layers 110′. In one embodiment, bottom surfaces of the first-tier memory openings 149 and the first-tier support openings 119 may be formed within the lower source-level semiconductor layer 112. The first-tier memory openings 149 and the first-tier support openings 119 may have a diameter in a range from 40 nm to 400 nm, such as from 80 nm to 200 nm, although lesser and greater thicknesses may be employed. The first etch mask layer can be removed, for example, by ashing after the first anisotropic etch process.

The first-tier memory openings 149 may be formed as clusters of first-tier memory openings 149. Each cluster of first-tier memory openings 149 may comprise an area of a memory block containing a plurality of rows of memory openings 49. Each row of first-tier memory openings 149 may comprise a plurality of first-tier memory openings 149 that are arranged along the first horizontal direction hd1 (which may be a word line direction) with a uniform pitch. The rows of first-tier memory openings 149 may be laterally spaced from each other along the second horizontal direction hd2 (which may be a bit line direction), which may be perpendicular to the first horizontal direction hd1. In one embodiment, each cluster of first-tier memory openings 149 may be formed as a two-dimensional periodic array of first-tier memory openings 149.

Referring to FIG. 3, a first sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the first-tier memory openings 149 and in the first-tier support openings 119 by a conformal deposition process. Excess portions of the first sacrificial fill material can be removed from above the top surface of the first-tier alternating stack (132, 142), for example, by a recess etch process. Each remaining portion of the first sacrificial fill material that fills a respective first-tier memory opening 149 constitutes a first sacrificial memory opening fill structure 147. Each remaining portion of the first sacrificial fill material that fills a respective first-tier support opening 119 constitutes a first sacrificial support opening fill structure 117.

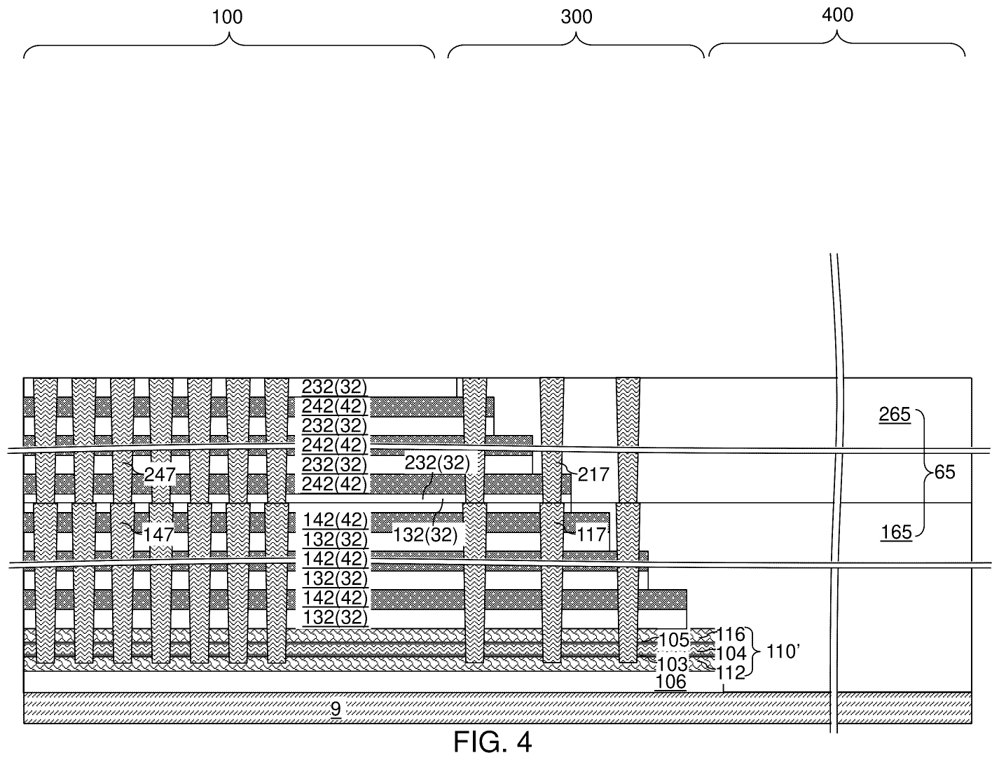

Referring to FIG. 4, a second-tier alternating stack (232, 242) of second insulating layers 232 and second spacer material layers may be formed above the first-tier alternating stack (132, 142) and the first stepped dielectric material portion 165. The second insulating layers 232 can be additional insulating layers 32 having a same material composition and a same thickness range as the first insulating layers 132. The second spacer material layers can be additional spacer material layers having a same material composition and a same thickness range as the first spacer material layers in the first-tier alternating stack (132, 142). In one embodiment, the second spacer material layers may comprise second sacrificial material layers 242. In this case, the second sacrificial material layers 242 can be additional sacrificial material layers 42 having a same material composition and a same thickness range as the first sacrificial material layers 142.

The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed.

The first-tier alternating stack (132, 142) and the second-tier alternating stack (232, 242) are collectively referred to as an alternating stack (32, 42) of insulating layers 32 and sacrificial material layers 42.

While an embodiment is described in which the second spacer material layers are formed as second sacrificial material layers 242, the second spacer material layers may be formed as second electrically conductive layers in an alternative embodiment. In this case, processing steps performed to replace the second sacrificial material layers 242 with second electrically conductive layers may be omitted.

Optional stepped surfaces are formed in the contact region 300 by patterning the second-tier alternating stack (232, 242). The stepped surfaces of the second-tier alternating stack (232, 242) may be laterally offset toward the memory array region 100 relative to the stepped surfaces of the first-tier alternating stack (132, 142) in a plan view. A second stepped cavity is formed within the volume from which portions of the second-tier alternating stack (232, 242) are removed through formation of the stepped surfaces. A “stepped cavity” refers to a cavity having stepped surfaces.

The second stepped cavity can have various stepped surfaces such that the horizontal cross-sectional shape of the second stepped cavity changes in steps as a function of the vertical distance from the top surface of the carrier substrate 9. In one embodiment, the second stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type.

Each second sacrificial material layer 242 other than a topmost second sacrificial material layer 242 within the alternating stack (232, 242) laterally extends farther than any overlying second sacrificial material layer 242 within the second-tier alternating stack (232, 242) in the terrace region. The stepped surfaces of the second-tier alternating stack (232, 242) continuously extend from a bottommost layer within the second-tier alternating stack (232, 242) to a topmost layer within the second-tier alternating stack (232, 242).

A second stepped dielectric material portion 265 (i.e., an insulating fill material portion) can be formed in the second stepped cavity by deposition of a dielectric material therein. For example, a dielectric material such as silicon oxide can be deposited in the stepped cavity. Excess portions of the deposited dielectric material can be removed from above the top surface of the topmost layer of the second-tier alternating stack (232, 242), for example, by chemical mechanical planarization (CMP). The remaining portion of the deposited dielectric material filling the second stepped cavity constitutes the second stepped dielectric material portion 265. If silicon oxide is employed for the second stepped dielectric material portion 265, the silicon oxide of the second stepped dielectric material portion 265 may, or may not, be doped with dopants such as B, P, and/or F. The combination of the first stepped dielectric material portion 165 and the second stepped dielectric material portion 265 may be collectively referred to as stepped dielectric material portions 65.

A second etch mask layer (such as a photoresist layer) can be formed over the second-tier alternating stack (232, 242), and can be lithographically patterned to form openings therein. A second anisotropic etch process can be performed to transfer the pattern of the openings in the second etch mask layer through the second stepped dielectric material portion 265 and the second-tier alternating stack (232, 242). Second-tier memory openings can be formed through the second-tier alternating stack (232, 242) directly on a top surface of a respective first sacrificial memory opening fill structure 147 in the memory array region 100. Second-tier support openings 119 can be formed through the second stepped dielectric material portion 165 and the second-tier alternating stack (232, 242) directly on a top surface of a respective first sacrificial support opening fill structure 117 in the contact region 300. Each of the second-tier memory openings and the second-tier support openings may have about the same diameter as the diameter of a respective underlying first sacrificial opening fill structure (147, 117). The second etch mask layer can be removed, for example, by ashing after the second anisotropic etch process.

A second sacrificial fill material, such as a carbon-based material (e.g., amorphous carbon, diamond-like carbon, or a doped carbon material), a high etch-rate dielectric material (e.g., borosilicate glass or organosilicate glass), or a polymer material, can be deposited in the second-tier memory openings and in the second-tier support openings by a conformal deposition process. Excess portions of the second sacrificial fill material can be removed from above the top surface of the second-tier alternating stack (232, 242), for example, by a recess etch process. Each remaining portion of the second sacrificial fill material that fills a respective second-tier memory opening constitutes a second sacrificial memory opening fill structure 247. Each remaining portion of the second sacrificial fill material that fills a respective second-tier support opening constitutes a second sacrificial support opening fill structure 217.

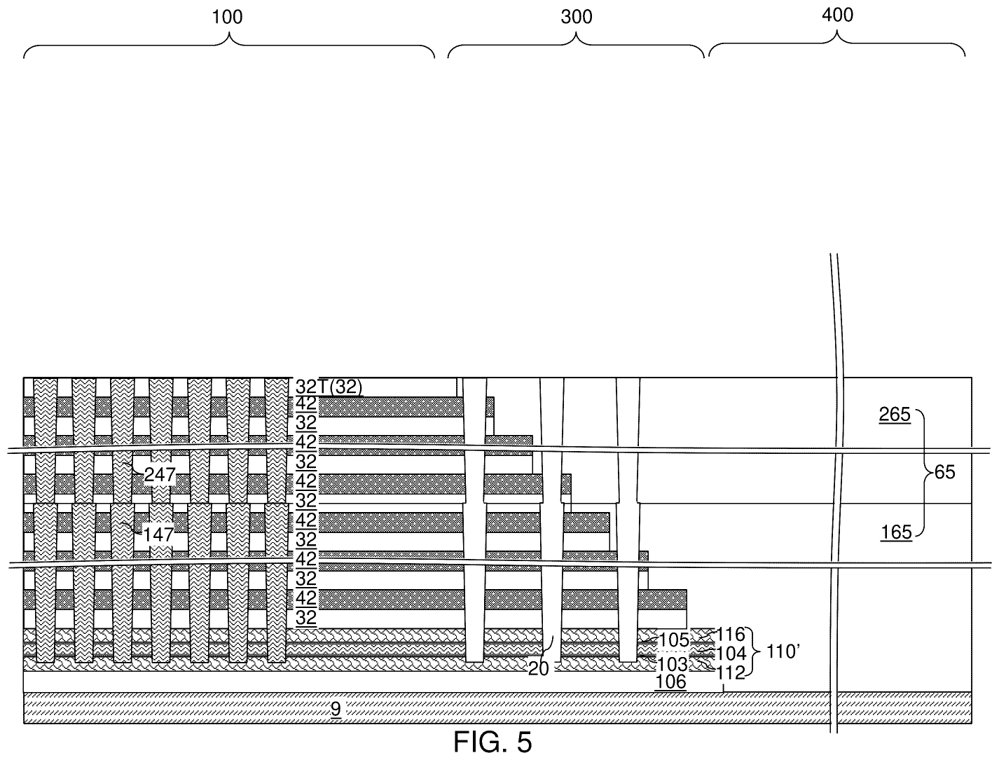

Referring to FIG. 5, a sacrificial mask layer (not shown) is formed over the memory array region 100. The exposed first and second sacrificial support opening fill structures (117, 217) in the contact region 300 are removed by selective etching or ashing to reopen the first-tier and second-tier support openings. A dielectric material, such as silicon oxide is deposited in the first-tier and second-tier support openings to form support pillar structures 20. The sacrificial mask layer is then removed by selective etching or ashing.

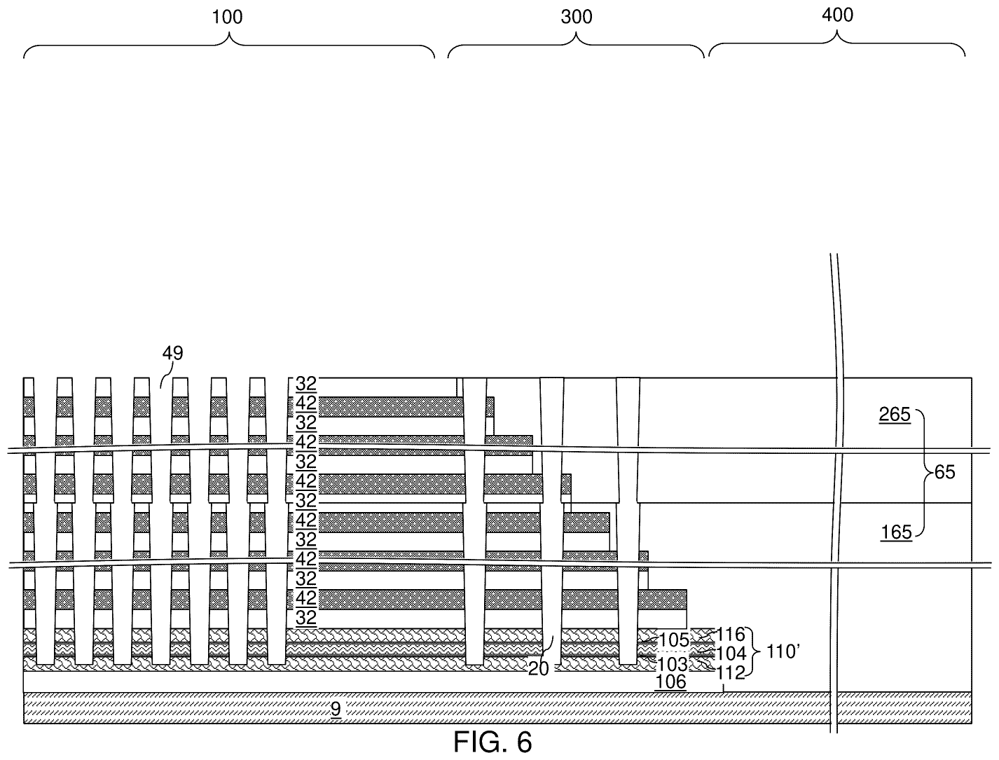

Referring to FIG. 6, the sacrificial memory opening fill structures (147, 247) in the memory array region 100 can be removed selective to the materials of the stepped dielectric material portions 65, the support pillar structures 20, and the alternating stack (32, 42). For example, an selective etch process or an ashing process may be employed to remove the sacrificial memory opening fill structures and portions of the optional etch stop liner in the memory array region 100. Voids are formed in the volumes of the memory openings 49.

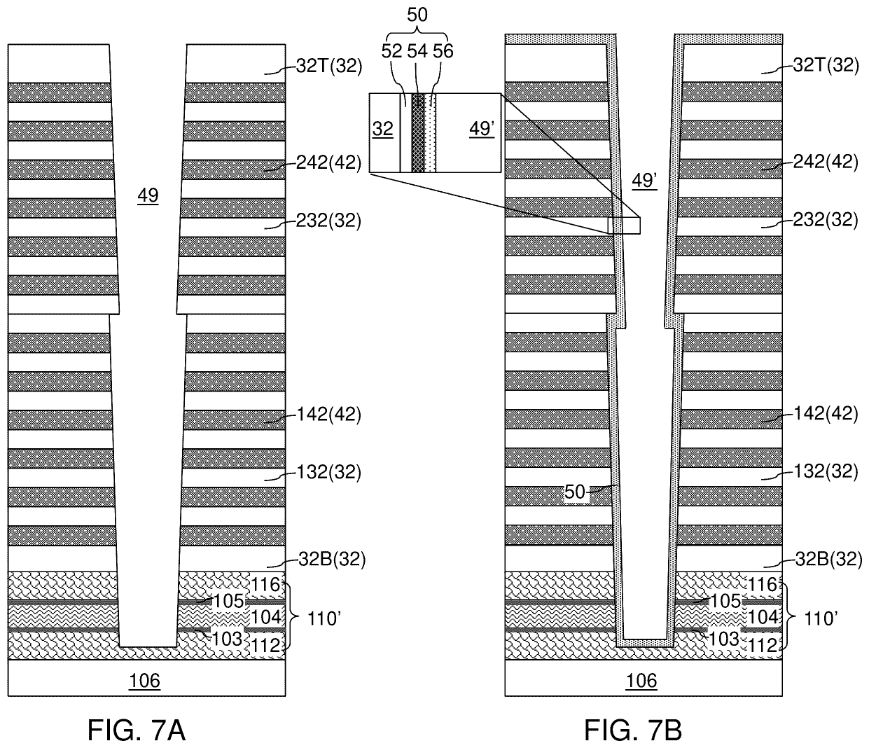

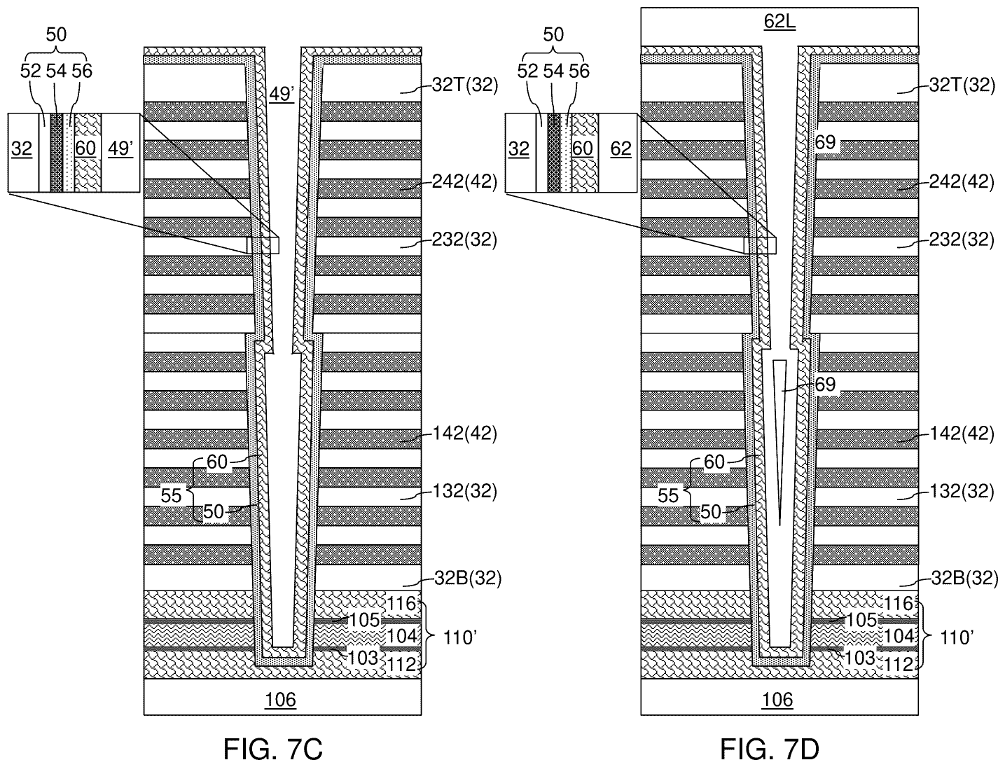

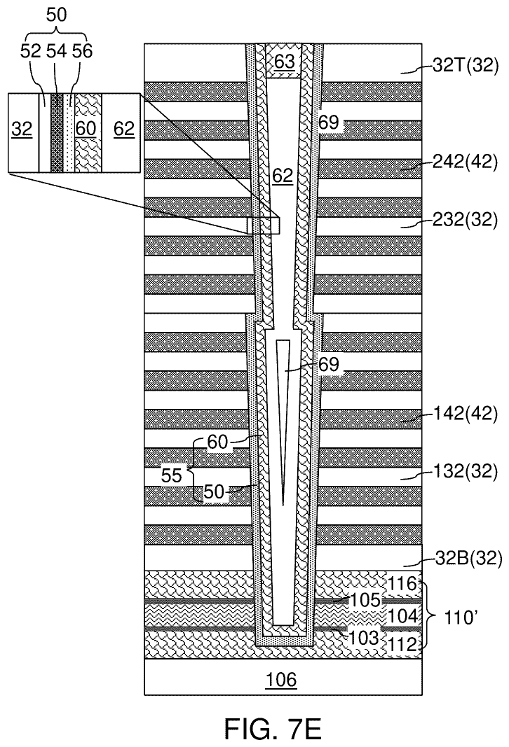

FIGS. 7A-7E are sequential vertical cross-sectional views of a memory opening 49 during formation of a memory opening fill structure 58.

Referring to FIG. 7A, a memory opening 49 is illustrated after the processing steps of FIG. 6. Each memory opening 49 vertically extends through each layer within the alternating stack (32, 42). The bottommost layer of the alternating stack (32, 42) may be a bottommost insulating layer 32B, and the topmost layer of the alternating stack (32, 42) may be a topmost insulating layer 32T.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. A memory cavity 49′ is present in an unfilled volume of the memory opening 49.

Referring to FIG. 7C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62. A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along long a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

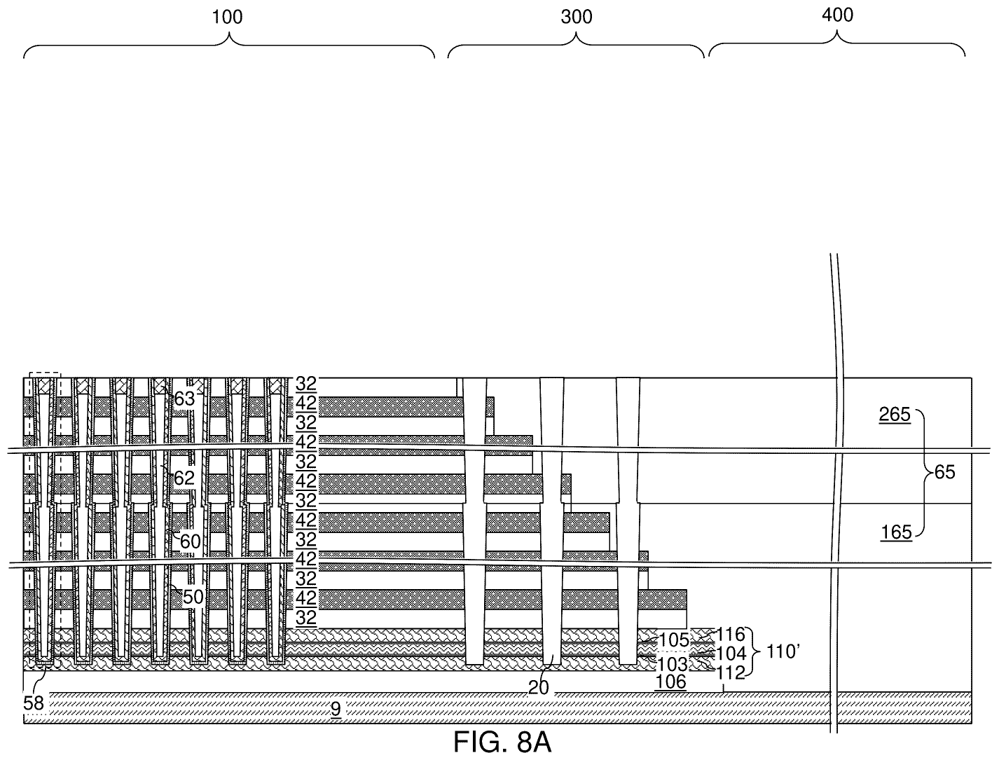

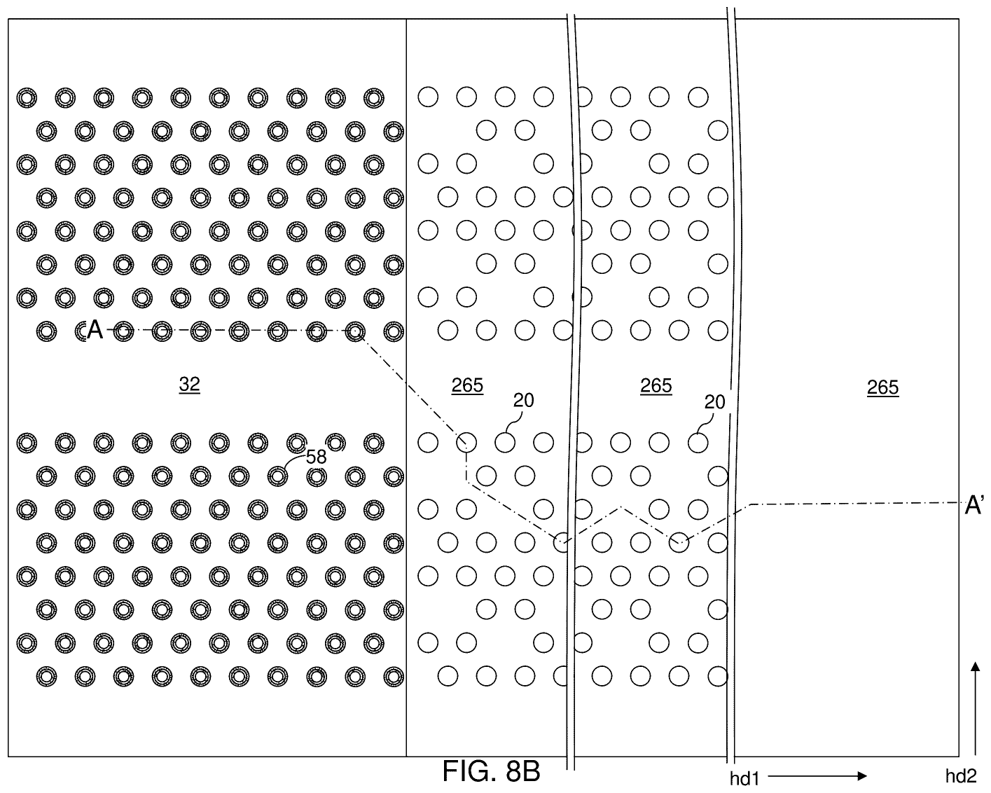

Referring to FIGS. 8A and 8B, the exemplary structure is illustrated after formation of memory opening fill structures 58 within the memory openings 49. The memory opening fill structures 58 are located in the memory openings 49. Each of the memory opening fill structures 58 comprises a respective vertical semiconductor channel 60, a respective vertical stack of memory elements (which may comprise portions of a memory material layer 54) located at levels of the sacrificial material layers 42, and a respective drain region 63 contacting a first end of the respective vertical semiconductor channel 60.

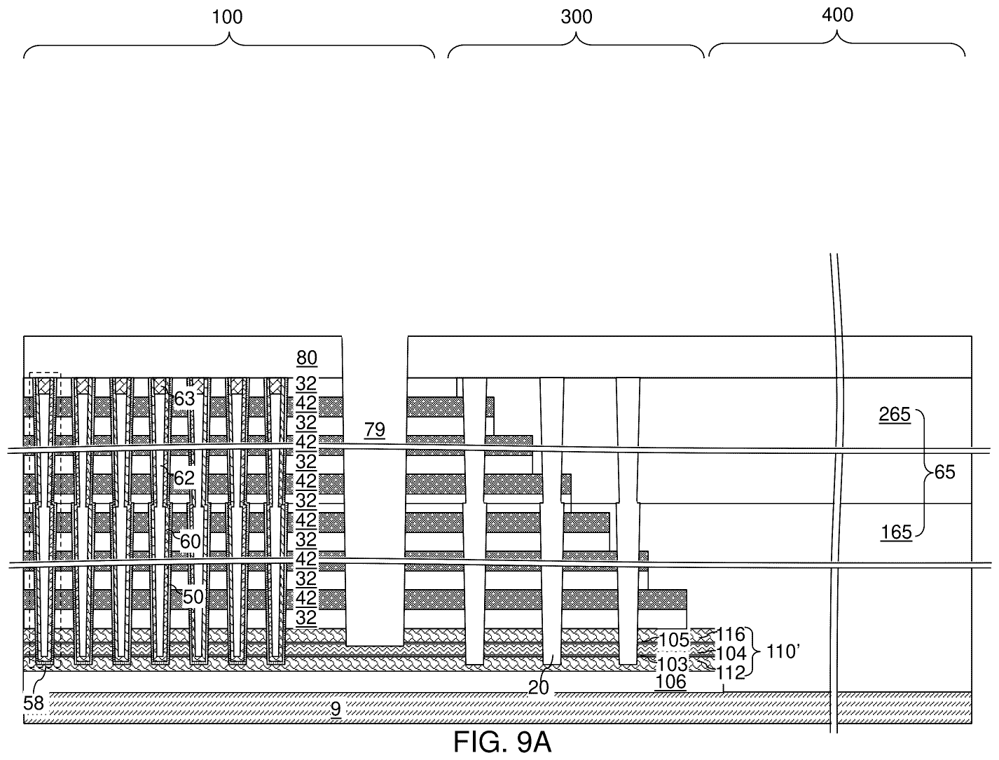

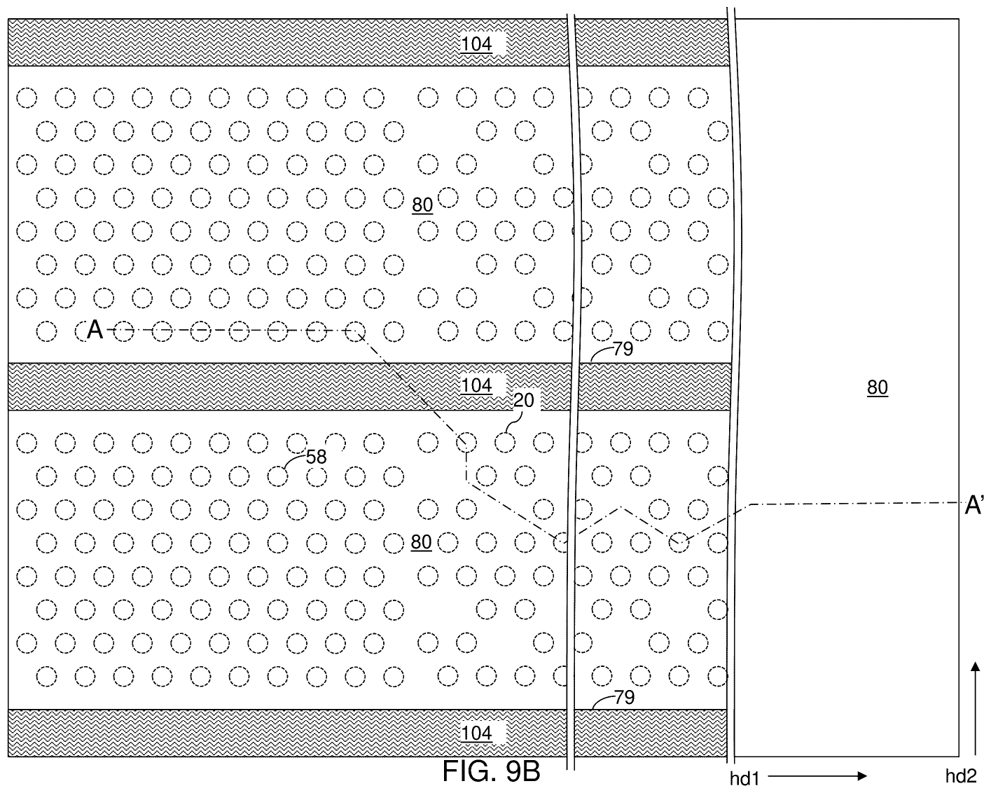

Referring to FIGS. 9A and 9B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portions 65, and into the in-process source-level material layers 110′. Lateral isolation trenches 79 laterally extending along the first horizontal direction hd1 can be formed through the alternating stack (32, 42), the stepped dielectric material portions 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to a surface of the source-level sacrificial layer 104. A surface of the source-level sacrificial layer 104 can be physically exposed underneath each lateral isolation trench 79. The photoresist layer can be subsequently removed, for example, by ashing.

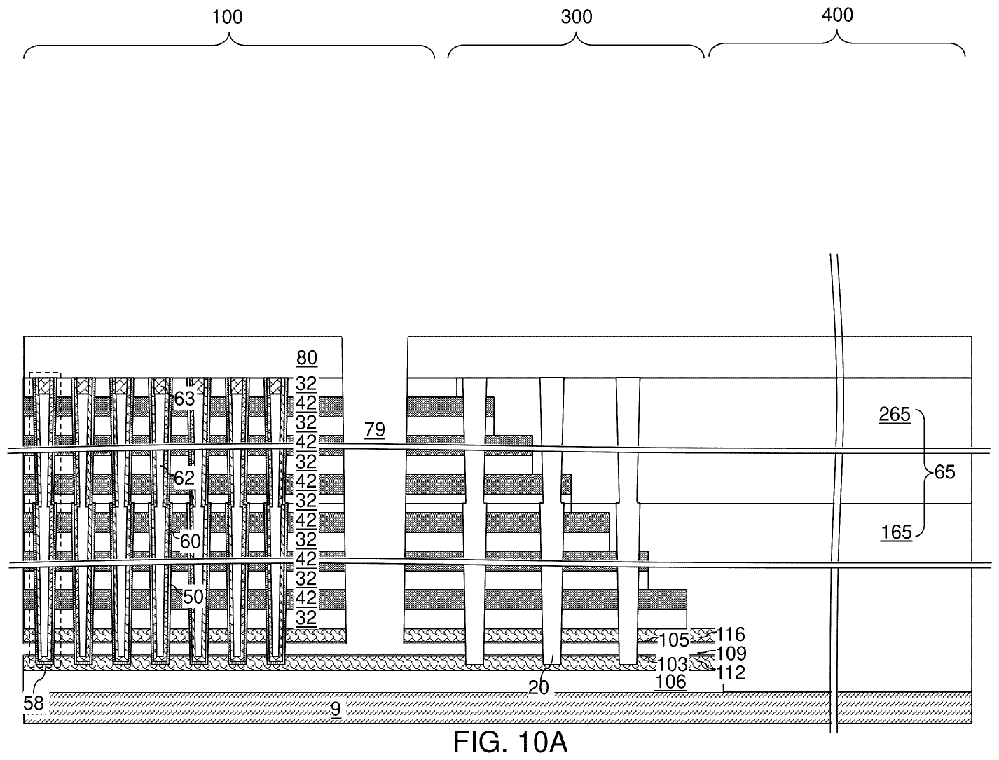

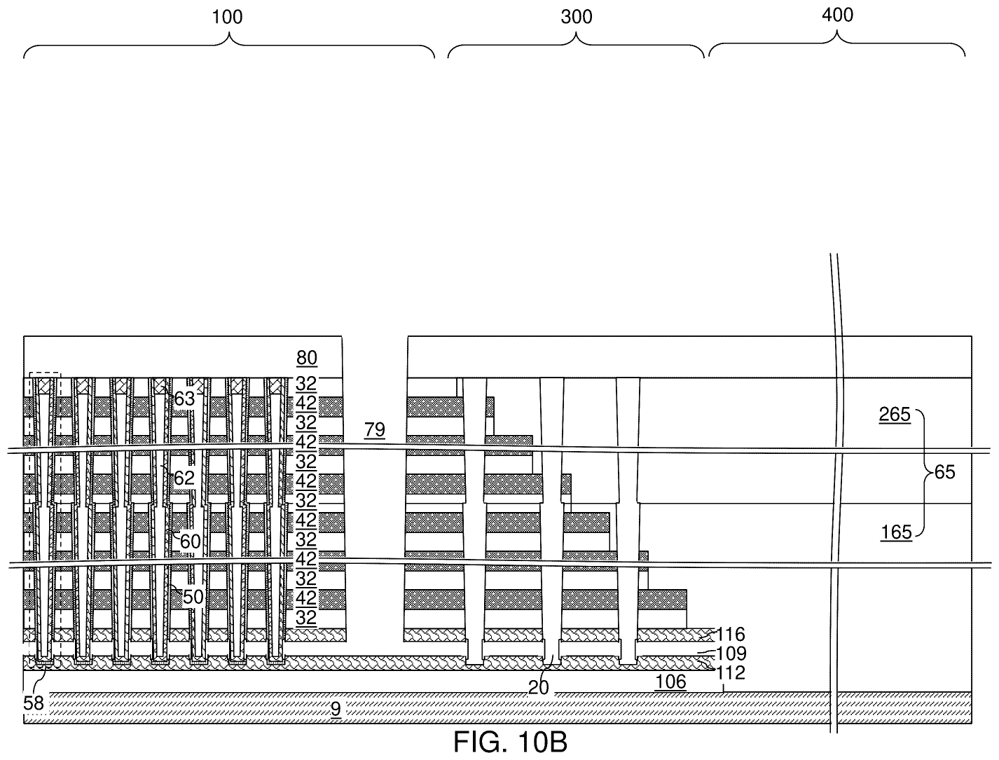

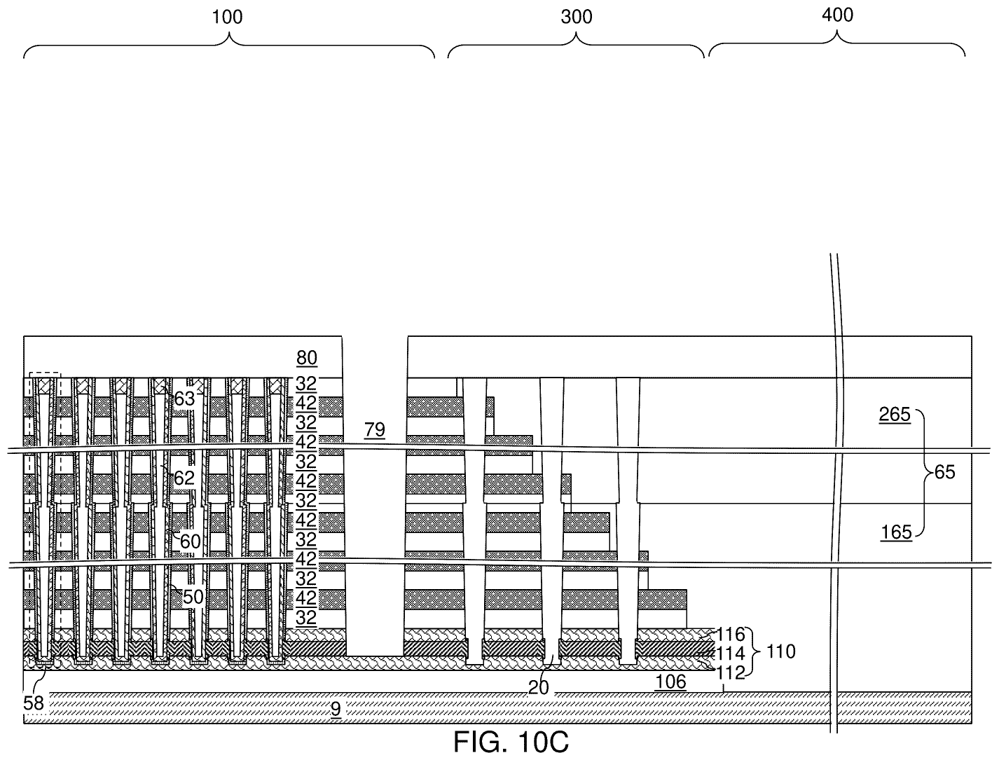

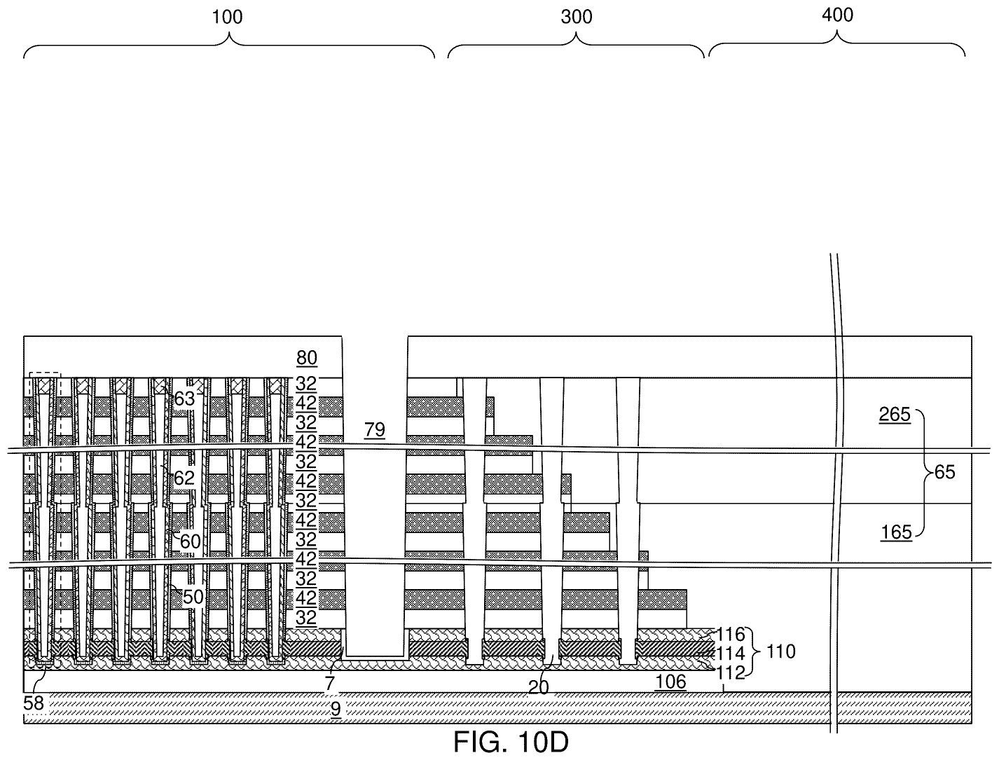

Referring to FIG. 10A, an etchant that etches the material of the source-level sacrificial layer 104 selective to the materials of the alternating stack (32, 42), the contact-level dielectric layer 80, the stepped dielectric material portions 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process.

For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the stepped dielectric material portions 65, the lower source-level semiconductor layer 112, and the upper source-level semiconductor layer 116. Wet etch chemicals such as hot TMY and TMAH selectively etch the undoped semiconductor source-level sacrificial layer 104 to doped semiconductor upper source-level semiconductor layer 116 and the lower source-level semiconductor layer 112. A source cavity 109 is formed in the volume from which the source-level sacrificial layer 104 is removed. Each of the memory opening fill structures 58 is physically exposed to the source cavity 109. Specifically, each of the memory opening fill structures 58 includes a sidewall and that are physically exposed to the source cavity 109.

Referring to FIG. 10B, a sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109.

Referring to FIG. 10C, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the first exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10¹⁹/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

Referring to FIG. 10D, an oxidation process can be performed to oxidize physically exposed surface portions of the source layer 110 into a semiconductor oxide liner 7.

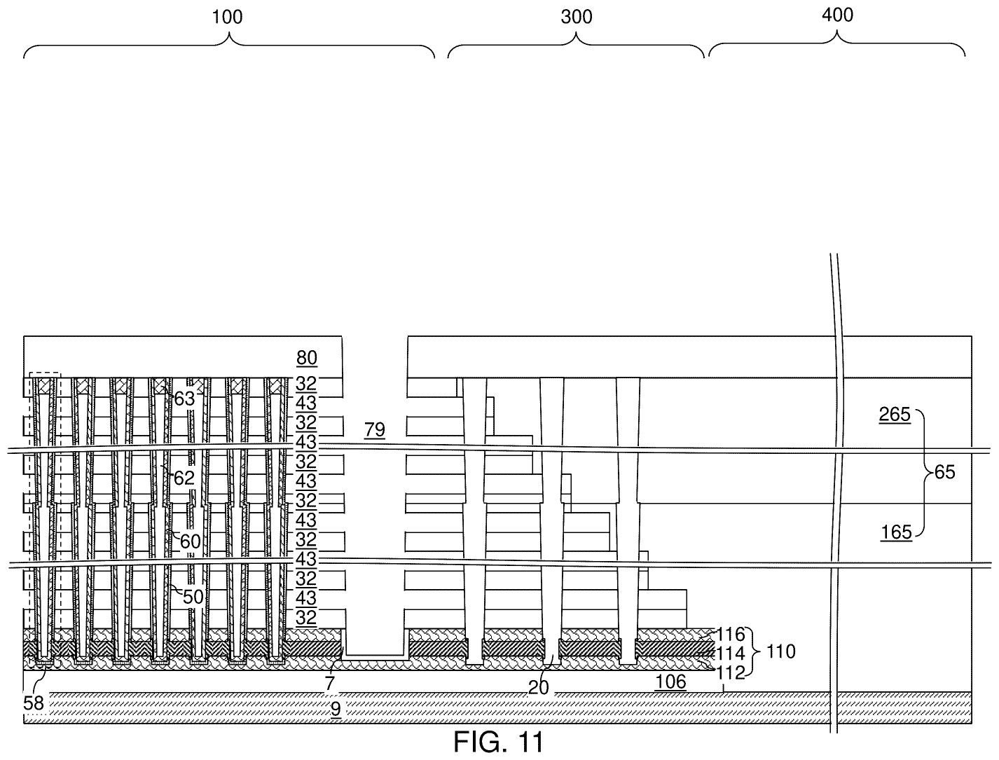

Referring to FIG. 11, an etchant that selectively etches the material of the sacrificial material layers 42 with respect to the material of the insulating layers 32 and the semiconductor oxide liner 7 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portions 65, and the material of the outermost layer of the memory films 50. In one embodiment, the sacrificial material layers 42 can include silicon nitride, and the materials of the insulating layers 32 and the stepped dielectric material portions 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the stepped dielectric material portions 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

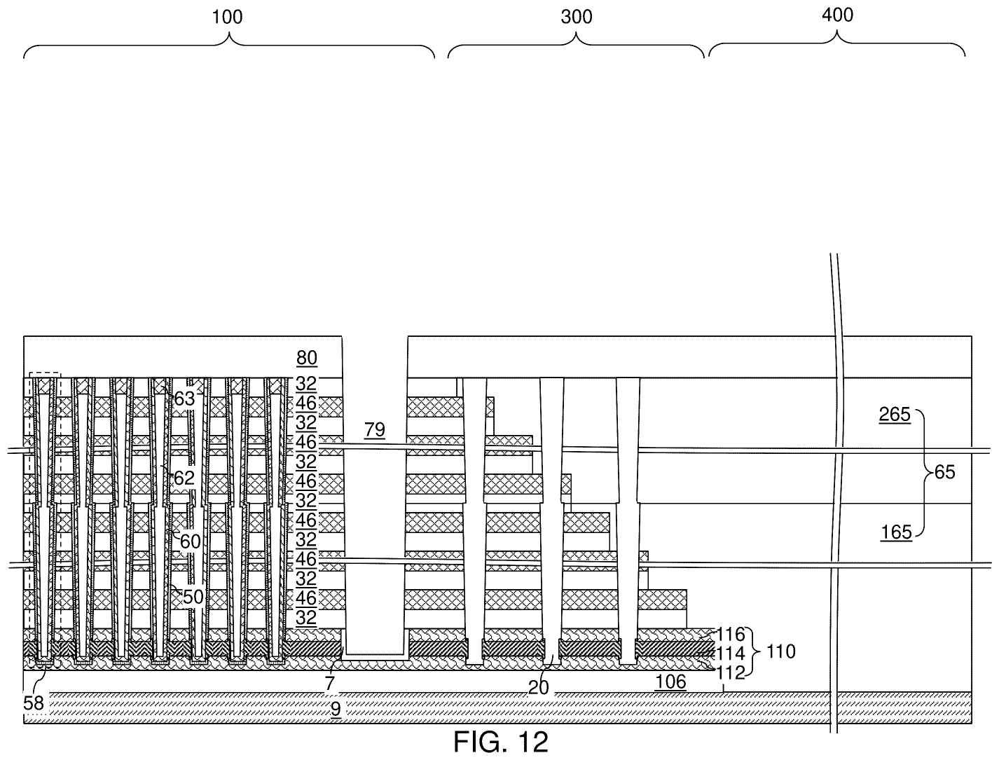

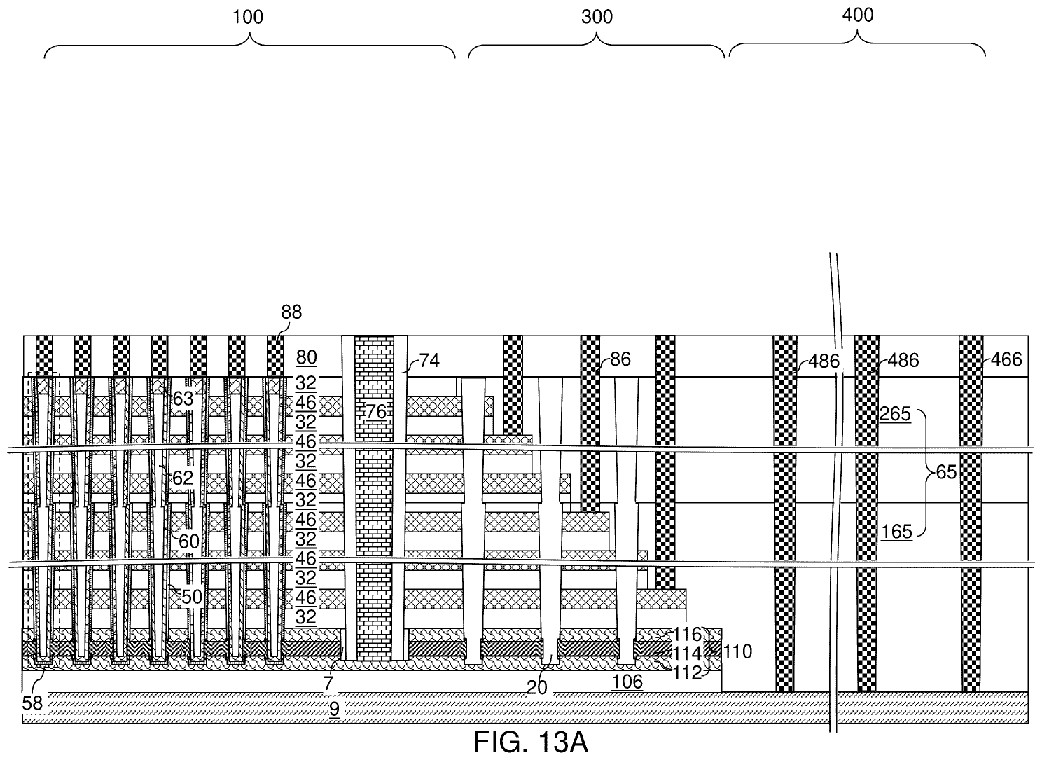

Referring to FIG. 12, an outer blocking dielectric layer (not expressly illustrated) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure.

Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

Generally, a memory device can be formed, which comprises an alternating stack (32, 46) of insulating layers 32 and electrically conductive layers 46, memory openings 49 vertically extending through the alternating stack (32, 46), and memory opening fill structures 58 located in the memory openings 49. Each of the memory opening fill structures 58 comprises a respective vertical semiconductor channel 60, a respective vertical stack of memory elements (which may comprise portions of a memory material layer 54) located at levels of the sacrificial material layers 42, and a respective drain region 63 contacting a first end of the respective vertical semiconductor channel 60. The electrically conductive layers 46 comprise select gate electrodes and word lines of the respective vertical stack of memory elements.

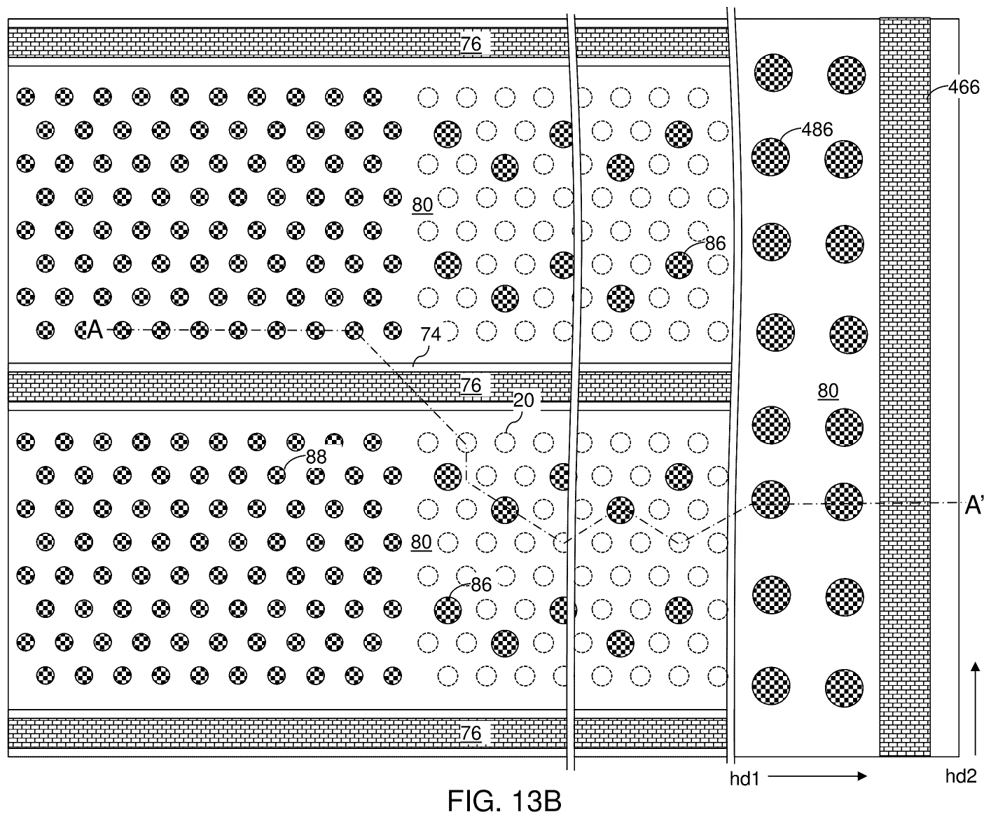

Referring to FIGS. 13A and 13B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Contact via structures (88, 86) can be formed through the contact-level dielectric layer 80, and optionally through the stepped dielectric material portions 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portions 65. In addition, connection via structures 486 can be formed through the contact-level dielectric layer 80 and the stepped dielectric material portions 65 in the peripheral region 400. In one embodiment, the connection via structures 486 may extend into an upper portion of the carrier substrate 9.

Further, an edge-seal via structure 466 can be formed along an outer periphery of the peripheral region 400 as a continuous ring-shaped structure. As used herein, a ring-shaped structure refers to a structure that is topologically homeomorphic to a ring, i.e., a structure that may be continuous deformed into the shape of a ring without creation of a new hole or destruction of any pre-existing hole. In one embodiment, the edge-seal via structure 466 may be formed as a component of a memory-side edge seal structure. The edge-seal via structure may laterally enclose all of the devices formed over the carrier substrate 9.

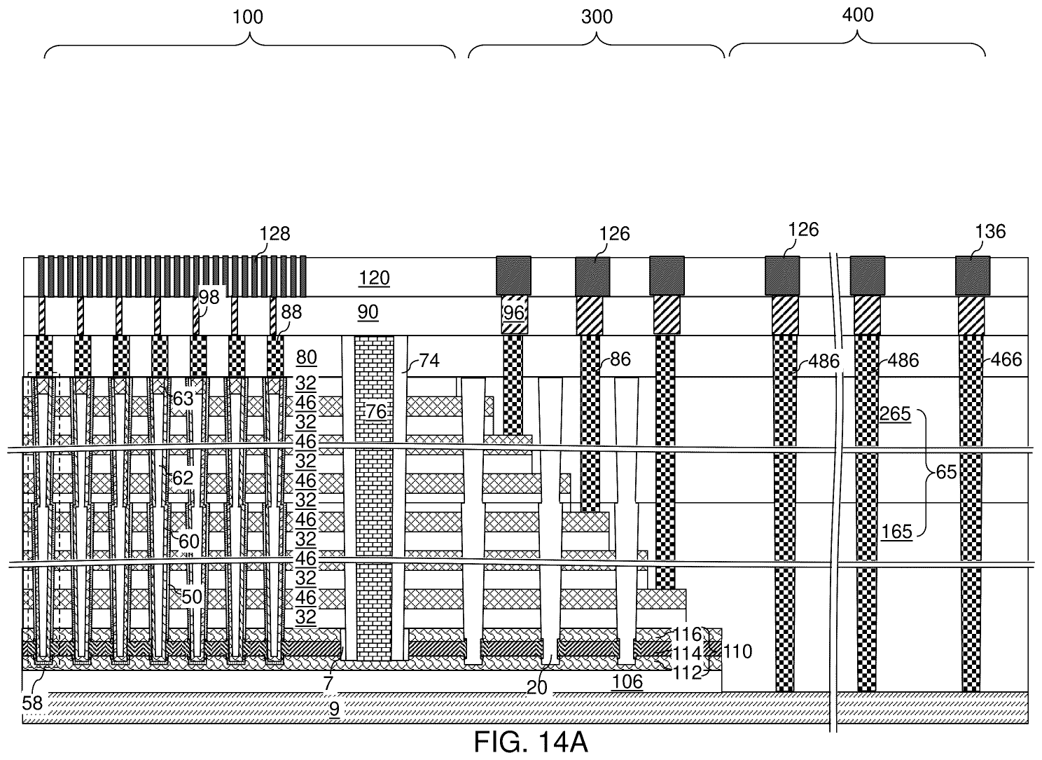

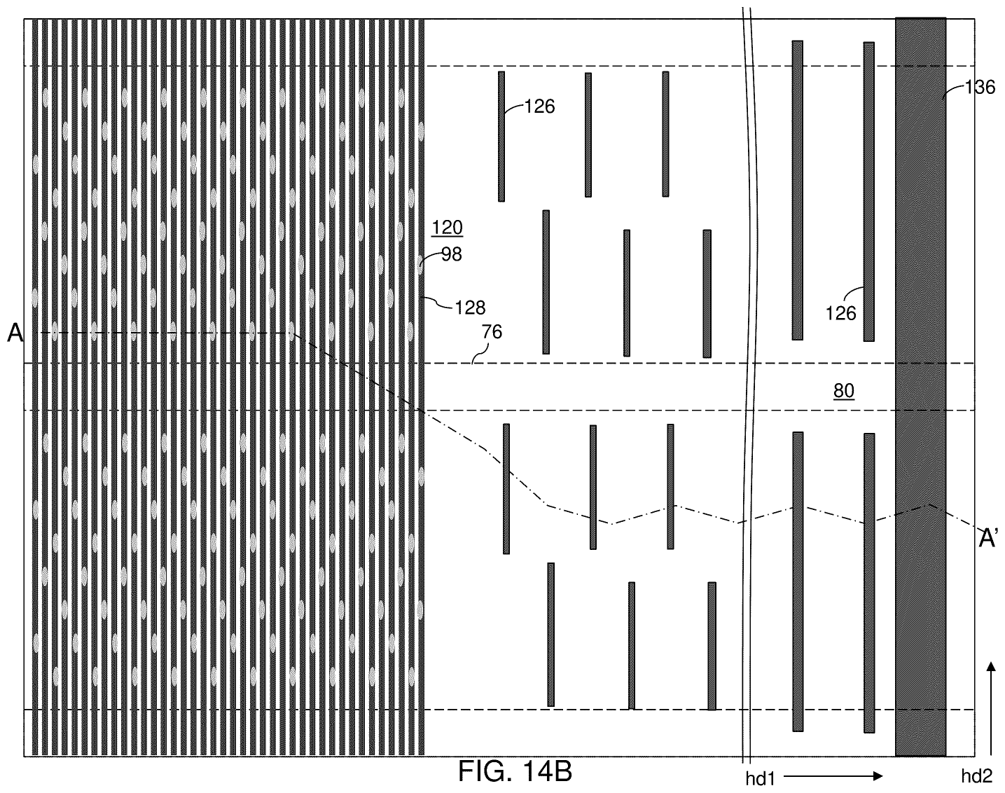

Referring to FIGS. 14A and 14B, a via-level dielectric layer 90 can be formed over the contact-level dielectric layer 80. The via-level dielectric layer 90 comprises a dielectric material, such as undoped silicate glass (e.g., silicon oxide), a doped silicate glass, or a porous or non-porous organosilicate glass. The via-level dielectric layer 90 may be deposited by a chemical vapor deposition or by spin coating. The thickness of the via-level dielectric layer 90 may be in a range from 50 nm to 300 nm, although lesser and greater thicknesses may also be employed.

Drain-connection via structures 98 and additional connection via structures 96 can be formed in the via-level dielectric layer 90. The drain-connection via structures 98 can be formed directly on the top surfaces of the drain contact via structures 88. The additional connection via structures 96 can be formed on a respective one of the layer contact via structures 86 and the connection via structures 486. An additional edge-seal via structure may be form on a top surface of the edge-seal via structure 466.

A bit-line-level dielectric layer 120 can be formed over the via-level dielectric layer 90. The bit-line-level dielectric layer 120 comprises a dielectric material, such as undoped silicate glass (e.g., silicon oxide), a doped silicate glass, or a porous or non-porous organosilicate glass. The bit-line-level dielectric layer 120 may be deposited by a chemical vapor deposition or by spin coating. The thickness of the bit-line-level dielectric layer 120 may be in a range from 50 nm to 300 nm, although lesser and greater thicknesses may also be employed.

Bit lines 128 and bit-line-level metal lines 126 can be formed in the bit-line-level dielectric layer 120. Each of the bit lines 128 may be formed on a respective subset of the drain-connection via structures 98. The bit-line-level metal lines 126 may be formed on a respective one of the additional connection via structures 96. An edge-seal line structure 136 may be form on a top surface of the additional edge-seal via structure.

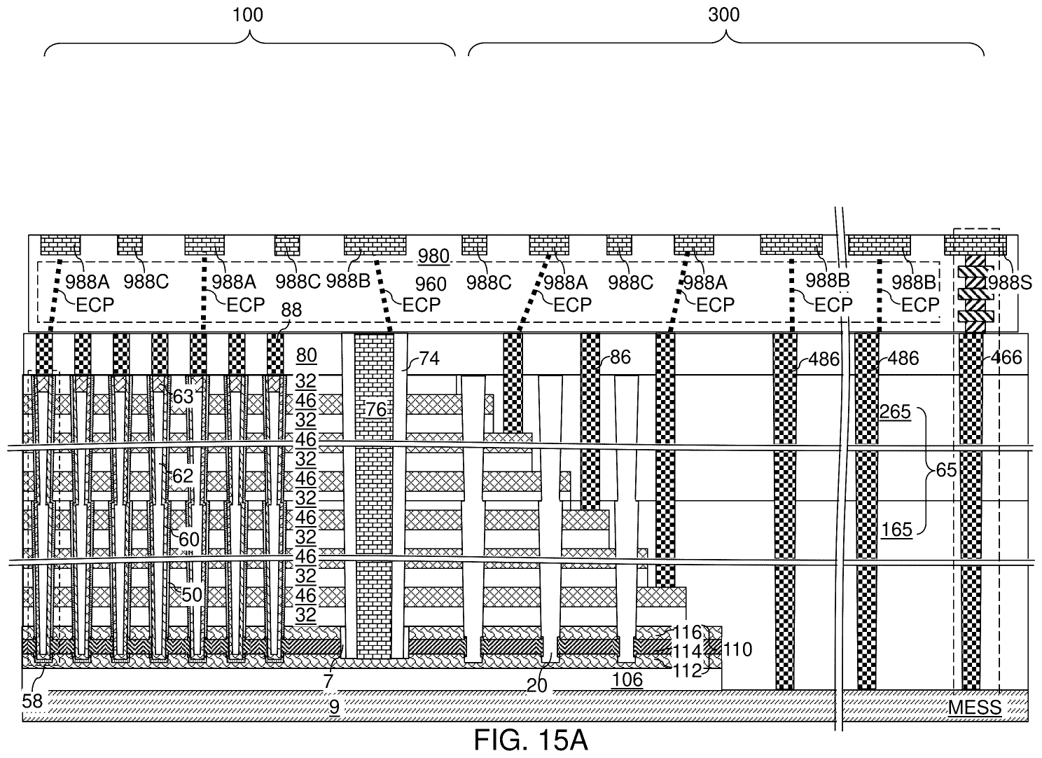

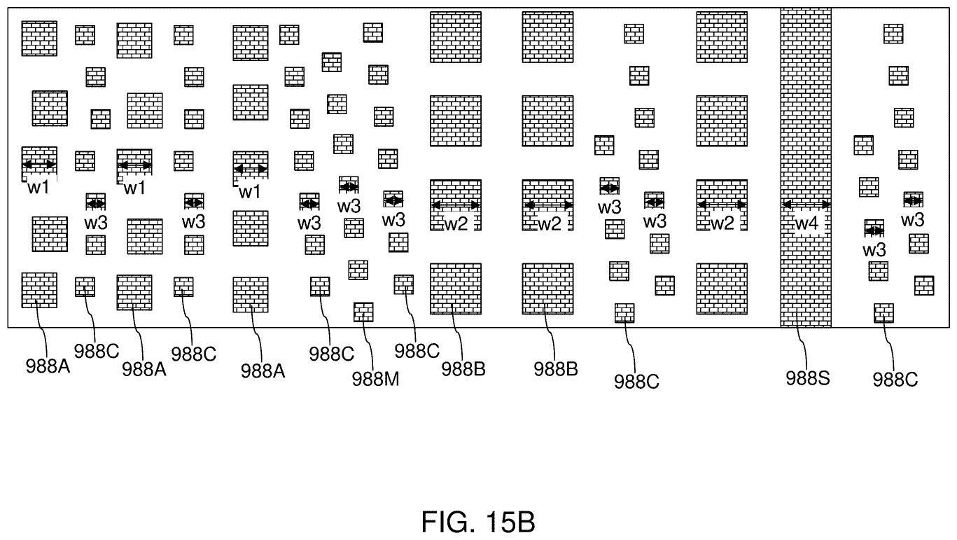

Referring to FIGS. 15A and 15B, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The via-level dielectric layer 90, the bit-line-level dielectric layer 120, and the additional dielectric material layers that are formed above the contact-level dielectric layer 80 are herein referred to as memory-side dielectric material layers 960. The drain-connection via structures 98, the additional connection via structures 96, the bit lines 128, the bit-line-level metal lines 126, the edge-seal line structure 136 and any additional metal interconnect structures are collectively referred to as memory-side dielectric material layers 960.

Metal bonding pads, which are herein referred to memory-side bonding pads 988, may be formed at the topmost level of the memory-side dielectric material layers 960. A subset of the memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

The memory-side bonding pads 988 comprise first-type memory-side bonding pads 988A electrically connected to the respective contact via structures 86 to the word lines 46 or to the respective bit lines 128, and second-type memory-side bonding pads 988B electrically connected to a subset of memory-side metal interconnect structures 980 for providing electrical connection the source layer 110 via the lateral isolation trench fill structure (i.e., local source interconnect) 76. Thus, electrically conductive paths ECP including a respective subset of the memory-side metal interconnect structures 980 may be formed between each of the first-type memory-side bonding pads 988A and a respective one of the drain contact via structures 88 (via the respective bit lines 128) or the layer contact via structures 86. Additional electrically conductive paths ECP may be formed between each of the second-type memory-side bonding pads 988B and a respective one of the lateral isolation trench fill structures (i.e., local source interconnect) 76.

In one embodiment, each of the first-type memory-side bonding pads 988A has a first bonding surface area and each of the second-type memory-side bonding pads 988B has a second bonding surface area that is larger than the first bonding surface area. It is understood that the area of all bonding pads is measured at a top surface, and thus, the area of a bonding pad refers to the area of the top surface (i.e., a bonding surface) of the bonding pad. Additionally, third-type memory-side bonding pads 988C can be provided. The third-type memory-side bonding pads 988C comprise dummy bonding pads which are not electrically connected to (i.e., which are electrically isolated from) the memory-side metal interconnect structures 980. The dummy bonding pads are used to enhance the bonding strength between the opposing die or wafers, but are not used to transmit electrical signals or power between the opposing die or wafers. In one embodiment, each of the third-type memory-side bonding pads 988C has a third bonding surface area that is smaller than the first bonding surface area. In one embodiment, the second-type surface area is at least 120%, such as 120 to 200% of the first-type surface area, the third-type surface area is 80% or less, such as 20 to 80% of the first-type surface area. In one embodiment, the first-type surface area 0.45 to 0.55 square microns, the second-type surface area 0.6 to 0.7 square microns, and the third-type surface area 0.3 to 0.4 square microns. Larger and smaller areas may also be used.

In one embodiment, the first-type memory-side bonding pads 988A, the second-type memory-side bonding pads 988B, and the third-type memory-side bonding pads 988C may be formed during the same processing step, and thus, may have a same thickness and have a same material composition. In one embodiment, each of the memory-side bonding pads 988 may comprise a metallic diffusion barrier liner including a conductive metallic nitride such as TiN, TaN, WN, and/or WN, and a metal bonding material such as copper.

In one embodiment, a subset of the first-type memory-side bonding pads 988A comprises a plurality of rows of first-type memory-side bonding pads 988A arranged along a horizontal direction. In one embodiment, a subset of the second-type memory-side bonding pads 988B comprises a plurality of rows of second-type memory-side bonding pads 988B arranged along the horizontal direction. In one embodiment, a first subset of the third-type memory-side bonding pads 988C is located between a pair of rows of first-type memory-side bonding pads 988A, and a second subset of the third-type memory-side bonding pads 988C is located between a pair of rows of second-type memory-side bonding pads 988B.

In one embodiment shown in FIG. 15B, the memory-side bonding pads 988 further comprise optional in-chip monitor bonding pads 988M that are electrically connected to a respective electrical node within the memory die 900 through a respective subset of the memory-side metal interconnect structures 980. As used herein, an “in-chip monitor bonding pad” refers to a bonding pad that is electrically connected to at least one electrical device so that electrical properties of the at least one electrical device can be monitored through in-line testing, for example, by connecting a probe to the bonding pad and applying a suitable test signal, such as a test voltage or a test current. In one embodiment, each of the in-chip monitor bonding pads 988M has a fourth bonding surface area that equals the second bonding surface area.

In one embodiment, each of the first-type memory-side bonding pads 988A has a first width W1 between a respective pair of parallel sidewalls thereof; each of the second-type memory-side bonding pads 988B has a second width W2 between a respective pair of parallel sidewalls thereof; and the second width W2 is greater than the first width W1. In one embodiment, each of the third-type memory-side bonding pads 988C has a third width W3 between a respective pair of parallel sidewalls thereof; and the third width W3 is less than the first width W1. In an illustrative example, the first width W1 may be in a range from 18 nm to 25 nm; the second width W2 may be in a range from 20 nm to 30 nm; and the third width W3 may be in a range from 15 nm to 22 nm.

In one embodiment, the memory die 900 further comprises a memory-side edge-seal ring structure MESS laterally surrounding an entirety of the memory-side metal interconnect structures 980 and comprising a ring-shaped memory-side bonding pad 988S located at a same level as the memory-side bonding pads 988. The ring-shaped memory-side bonding pad 988S may have a fourth width W4, which equals to the second width W2. The ring-shaped memory-side bonding pad 988S has a larger surface area than the second-type surface area of the second-type bonding pads 988B. In one embodiment, a subset of the third-type memory-side bonding pads 988C may be located outside the ring-shaped memory-side bonding pad 988S.

The second-type memory-side bonding pads 988B have a larger surface area than the first-type memory-side bonding pads 988A and the third-type memory-side bonding pads 988C, because the second-type memory-side bonding pads 988B have the largest parasitic capacitance with the source layer 110, which extends along a large portion of the memory die 900. Without wishing to be bound by a particular theory, it is believed that the second-type memory-side bonding pads 988B experience the largest amount of charging during the plasma treatment due to the parasitic capacitance, and have the highest negative charge after the plasma treatment. Therefore, the second-type memory-side bonding pads 988B have the largest surface area because they attract the largest amount of precipitated positive copper ions from the cleaning solution during the cleaning step. By increasing the surface area of the second-type memory-side bonding pads 988B, the precipitated copper ions are distributed among a larger surface area, and the average height of the protrusions caused by the precipitated copper ions is reduced.

The third-type memory-side bonding pads 988C have the smallest surface area because they are electrically isolated from the memory side metal interconnect structures 980. Therefore, the third-type memory-side bonding pads 988C experience the smallest amount of parasitic capacitance, and the lowest amount of charging during the plasma treatment. Therefore, the area of the third-type memory-side bonding pads 988C is reduced to reduce the amount of dissolution of copper ions from these pads during the cleaning process. The reduced amount of dissolution of the copper ions reduces the amount of pitting in these pads.

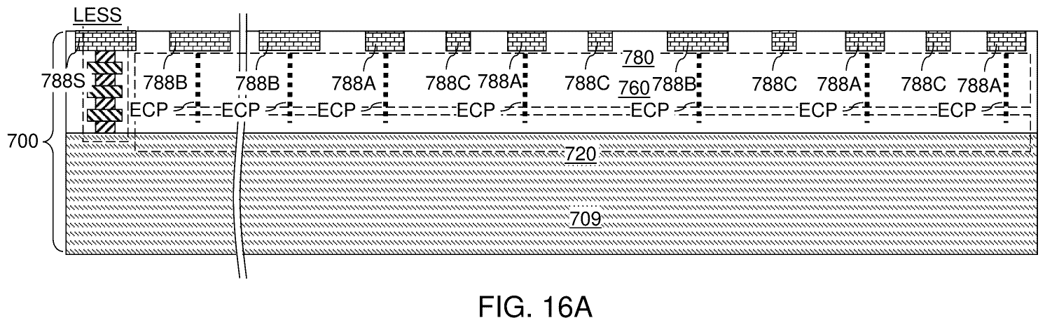

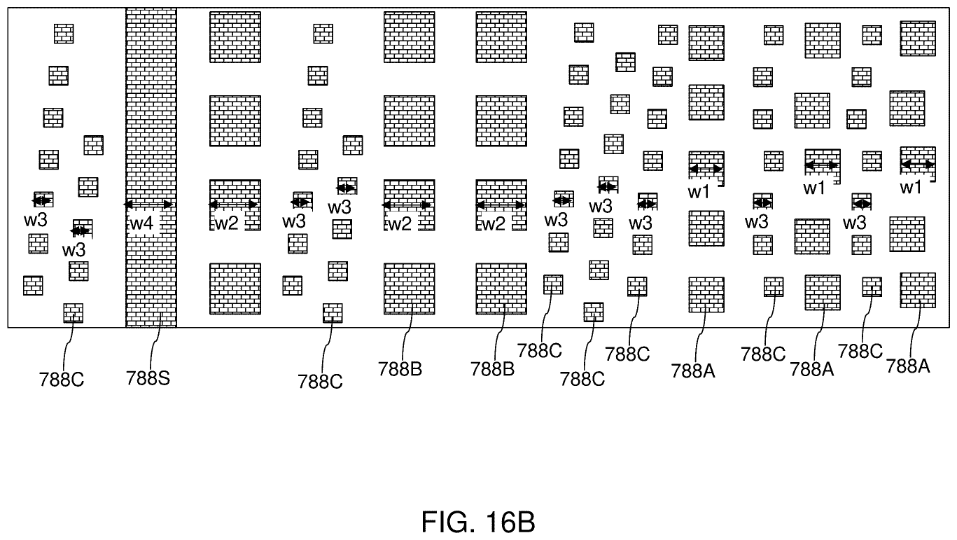

Referring to FIGS. 16A and 16B, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63 (via the bit lines 128), and the source layer 110 via the local source interconnect 76. The peripheral circuit 720 can be configured to control operation of the vertical stack of memory elements (e.g., memory cells) in the memory array in the memory die 900.

In one embodiment, the peripheral circuit 720 including a source line driver, word line drivers, and bit line drivers, and logic-side dielectric material layers 760 embedding logic-side metal interconnect structures 780 and logic-side bonding pads 788. The pattern of the logic-side bonding pads 788 may be a mirror image pattern of the pattern of the memory-side bonding pads 988. In one embodiment, the logic-side bonding pads 788 comprise first-type logic-side bonding pads 788A arranged in a mirror image pattern of the pattern of the first-type memory-side bonding pads 988A; second-type logic-side bonding pads 788B arranged in a mirror image pattern of the pattern of the second-type memory-side bonding pads 988B and the in-chip monitor bonding pads 988M; and third-type logic-side bonding pads 788C arranged in a mirror image pattern of the pattern of the combination of the third-type memory-side bonding pads 988C and t.

In one embodiment, the first-type logic-side bonding pads 788A are electrically connected to a respective one of the word line drivers and the bit line drivers through a respective second subset of the logic-side metal interconnect structures 780. Thus, an electrically conductive path ECP may be provided between each of the first-type logic-side bonding pads 788A and a respective one of the word line drivers and the bit line drivers. In one embodiment, the second-type logic-side bonding pads 788B are electrically connected to at least one source line driver through a first subset of the logic-side metal interconnect structures 780. Thus, an electrically conductive path ECP may be provided between each of the second-type logic-side bonding pads 788B and a respective source driver. In one embodiment, the third-type logic-side bonding pads 788C are electrically isolated from the logic-side metal interconnect structures 780.

In one embodiment, the logic die 700 comprises a logic-side edge-seal ring structure LESS laterally surrounding an entirety of the logic-side metal interconnect structures 780 and comprising a ring-shaped logic-side bonding pad 788S located at a same level as the logic-side bonding pads 788 and having a pattern that is a mirror image pattern of the ring-shaped memory-side bonding pad 988S. The ring-shaped logic-side bonding pad 788S may have the fourth width W4, which may be the same as the second width W2. A subset of the third-type logic-side bonding pads 788C may be located outside the ring-shaped logic-side bonding pad 788S.

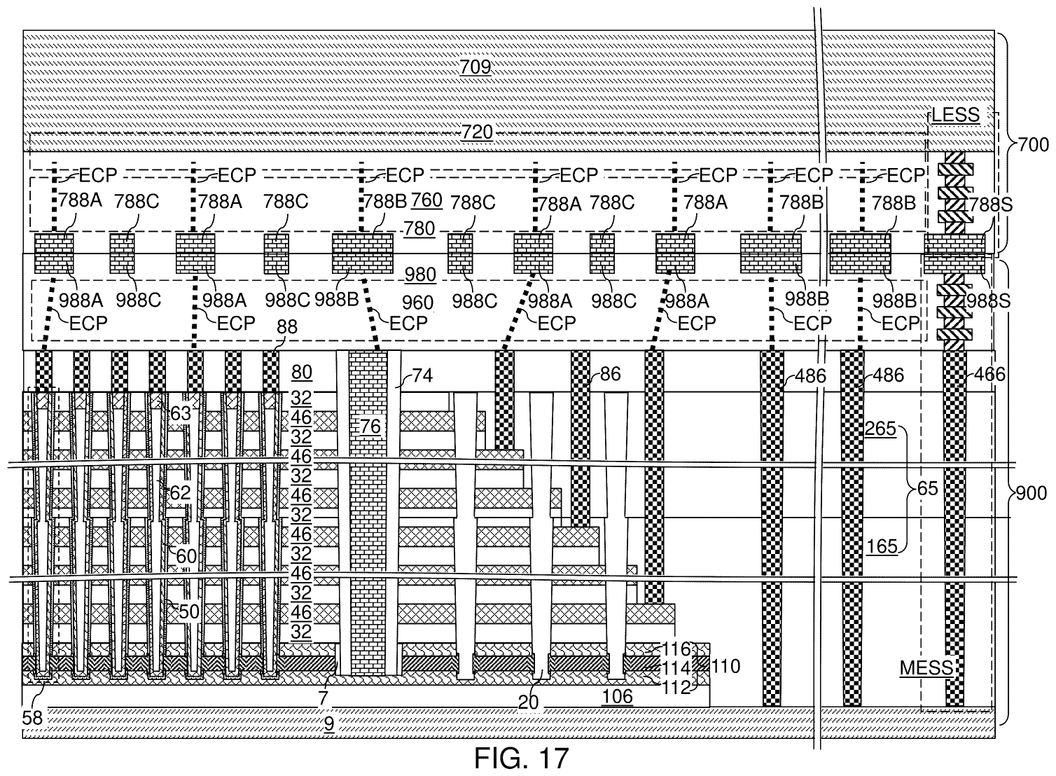

Referring to FIG. 17, the logic die 700 can be attached to the memory die 900, for example, by bonding the logic-side bonding pads 788 to the memory-side bonding pads 988 at a bonding interface. Plasma treatment processes and chemical cleaning processes can be performed to clean the surfaces of the memory-side bonding pads 988 and the logic-side bonding pads 788 prior to bonding the logic-side bonding pads 788 to the memory-side bonding pads 988.

The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900. A bonded assembly of the memory die 900 and the logic die 700 is provided.

The logic-side bonding pads 788 can be bonded to the memory-side bonding pads 988 via metal-to-metal bonding, such as copper-to-copper bonding. Each logic-side bonding pad 788 that is bonded to a respective memory-side bonding pad 988 is electrically connected to the respective memory-side bonding pad 988. The logic-side bonding pads 788 comprise first-type logic-side bonding pads 788A that are bonded to the first-type memory-side bonding pads 988A; second-type logic-side bonding pads 788B that are bonded to the second-type memory-side bonding pads 988B; and third-type logic-side bonding pads 788C that are bonded to the third-type memory-side bonding pads 988C. In one embodiment, each bonded pair of a third-type memory-side bonding pad 988C and a third-type logic-side bonding pad 788C is electrically floating. In one embodiment, a subset of the logic-side bonding pads 788 is bonded to the in-chip monitor bonding pads 988M and does not contact any of the logic-side metal interconnect structures 780.

In one embodiment, the memory die 900 comprises a memory-side edge-seal ring structure LESS laterally surrounding an entirety of the memory-side metal interconnect structures 980 and comprising a ring-shaped memory-side bonding pad 988S located at a same level as the memory-side bonding pads 988 and bonded to the ring-shaped memory-side bonding pad 988S. The logic die 700 comprises a logic-side edge-seal ring structure LESS laterally surrounding an entirety of the logic-side metal interconnect structures 780 and comprising a ring-shaped logic-side bonding pad 788S located at a same level as the logic-side bonding pads 788 and bonded to the ring-shaped memory-side bonding pad 988S. In one embodiment, a subset of the third-type memory-side bonding pads 988C is located outside the ring-shaped memory-side bonding pad 988S, and a subset of the logic-side bonding pads 788 located outside the ring-shaped logic-side bonding pad 788S, and is bonded to the subset of the third-type memory-side bonding pads 988C.

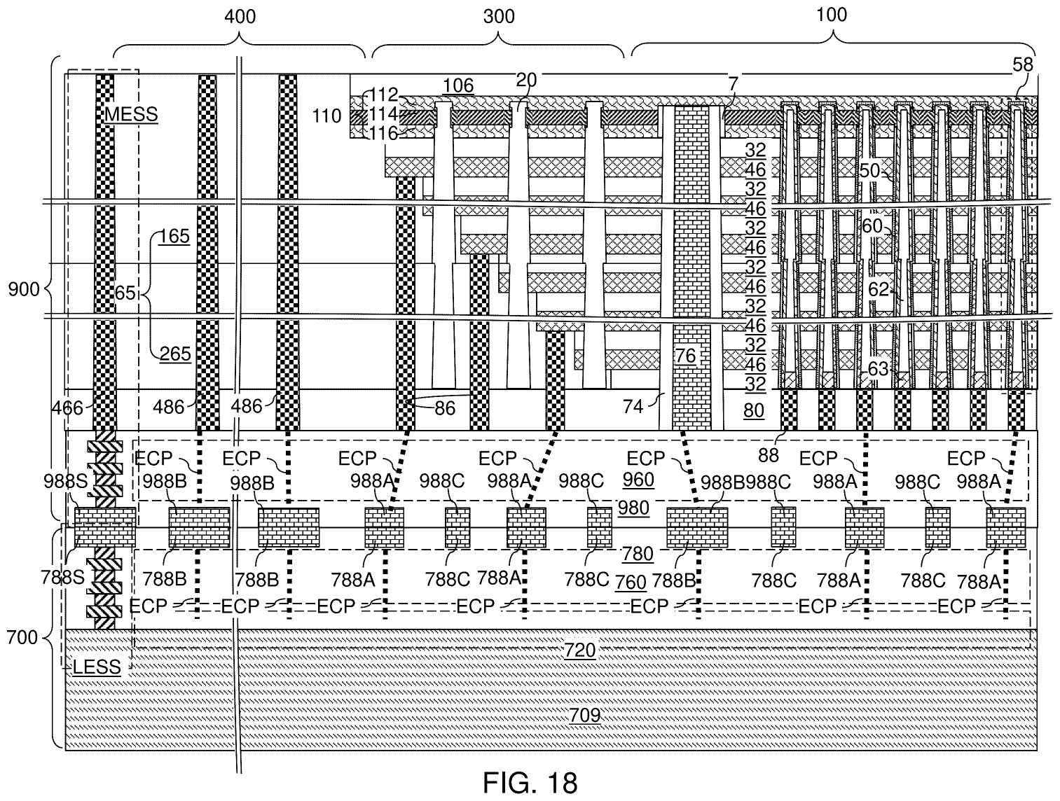

Referring to FIG. 18, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the stopper insulating layer 106 may be employed as a polish stop or etch stop, respectively.

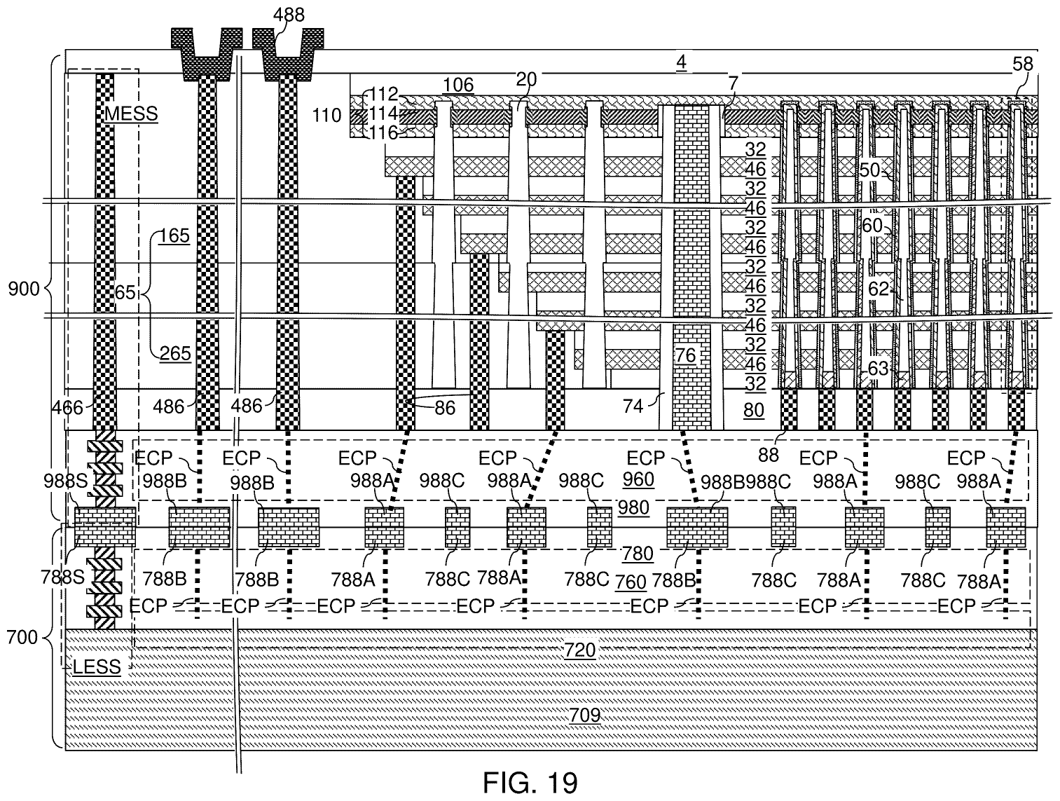

Referring to FIG. 19, an optional backside insulating layer 4 can be formed on the backside surface of the stopper insulating layer 106, and backside contact pad structures 488 can be formed on an end surface of a respective one of the connection via structures 486.

Referring to all drawings and according to various embodiments of the present disclosure, a semiconductor structure comprising a memory die 900 is provided. The memory die 900 comprises: a source layer 110; an alternating stack (32, 46) of insulating layers 32 and electrically conductive layers 46; memory openings 49 vertically extending through the alternating stack (32, 46); memory opening fill structures 58 located in the memory openings 49, wherein each of the memory opening fill structures 58 comprises a respective vertical semiconductor channel 60, a respective vertical stack of memory elements (comprising portions of a memory material layer 54 or discreet charge storage regions or floating gates) located at levels of the electrically conductive layers 46, and a respective drain region 63 contacting a first end of the respective vertical semiconductor channel 60, wherein a second end of the respective vertical semiconductor channel 60 is electrically connected to the source layer 110, and wherein the electrically conductive layers 46 comprise word lines of the respective vertical stack of memory elements; bit lines 128 electrically connected to a respective subset of the drain regions 63; and memory-side dielectric material layers 960 embedding memory-side metal interconnect structures 980 and memory-side bonding pads 988. The memory-side bonding pads 988 comprise first-type memory-side bonding pads 988A electrically connected to a respective one of the word lines or the bit lines 128, and second-type memory-side bonding pads 988B electrically connected to the source layer 110, wherein each of the first-type memory-side bonding pads 988A has a first bonding surface area and each of the second-type memory-side bonding pads 988B has a second bonding surface area that is larger than the first bonding surface area.

In one embodiment, the memory-side bonding pads 988 further comprise third-type memory-side bonding pads 988C that are electrically isolated from the memory-side metal interconnect structures 980; and each of the third-type memory-side bonding pads 988C has a third bonding surface area that is smaller than the first bonding surface area.

In one embodiment, the second bonding surface area is at least 120% of the first bonding surface area; and the third bonding surface area is 80% or less of the firs bonding surface area. In one embodiment, the first-type memory-side bonding pads 988A, the second-type memory-side bonding pads 988B, and the third-type memory-side bonding pads 988C have a same thickness and have a same material composition.

In one embodiment, a subset of the first-type memory-side bonding pads 988A is arranged in a plurality of rows of first-type memory-side bonding pads 988A arranged along a horizontal direction; a subset of the second-type memory-side bonding pads 988B is arranged in a plurality of rows of second-type memory-side bonding pads 988B arranged along the horizontal direction; and a first subset of the third-type memory-side bonding pads 988C is located between a pair of rows of first-type memory-side bonding pads 988A; and a second subset of the third-type memory-side bonding pads 988C is located between a pair of rows of second-type memory-side bonding pads 988B.

In one embodiment, the semiconductor structure further comprises a logic die 700 comprising: a peripheral circuit 720 including a source line driver, word line drivers, and bit line drivers; and logic-side dielectric material layers 760 embedding logic-side metal interconnect structures 780 and logic-side bonding pads 788 that are bonded to the memory-side bonding pads 988.

In one embodiment, the logic-side bonding pads 788 comprise: first-type logic-side bonding pads 788A that are bonded to the first-type memory-side bonding pads 988A; second-type logic-side bonding pads 788B that are bonded to the second-type memory-side bonding pads 988B and that have a larger bonding surface area than the first-type logic-side bonding pads; and third-type logic-side bonding pads 788C that are bonded to the third-type memory-side bonding pads 988C and that have a smaller bonding surface area than the first-type logic-side bonding pads.

In one embodiment, the third-type logic-side bonding pads 788C are electrically isolated from the logic-side metal interconnect structures 780. In one embodiment, each bonded pair of a third-type memory-side bonding pad 988C and a third-type logic-side bonding pad 788C is electrically floating.

In one embodiment, the first-type logic-side bonding pads 788A are electrically connected to a respective one of the word line drivers and the bit line drivers through a respective first subset of the logic-side metal interconnect structures 780; and the second-type logic-side bonding pads 788B are electrically connected to the source line driver through a second subset of the logic-side metal interconnect structures 780.

In one embodiment, each of the first-type memory-side bonding pads 988A has a first width W1 between a respective pair of parallel sidewalls thereof; each of the second-type memory-side bonding pads 988B has a second width W2 between a respective pair of parallel sidewalls thereof; and the second width W2 is greater than the first width W1. In one embodiment, each of the third-type memory-side bonding pads 988C has a third width W3 between a respective pair of parallel sidewalls thereof; and the third width W3 is less than the first width W1.

In one embodiment, the memory-side bonding pads 988 further comprise in-chip monitor bonding pads 988M that are electrically connected to a respective electrical node within the memory die 900 through a respective subset of the memory-side metal interconnect structures 980; and each of the in-chip monitor bonding pads 988M has a fourth bonding surface area that equals the second bonding surface area. In one embodiment, a subset of the logic-side bonding pads 788 is bonded to the in-chip monitor bonding pads 988M and does not contact any of the logic-side metal interconnect structures 780.

In one embodiment, the memory die 900 further comprises a memory-side edge-seal ring structure laterally surrounding an entirety of the memory-side metal interconnect structures 980 and comprising a ring-shaped memory-side bonding pad 988S located at a same level as the memory-side bonding pads 988; the logic die 700 further comprises a logic-side edge-seal ring structure laterally surrounding an entirety of the logic-side metal interconnect structures 780 and comprising a ring-shaped logic-side bonding pad 788S located at a same level as the logic-side bonding pads 788 and bonded to the ring-shaped memory-side bonding pad 988S; a subset of the third-type memory-side bonding pads 988C is located outside the ring-shaped memory-side bonding pad 988S; and another subset of the logic-side bonding pads 788 is bonded to the subset of the third-type memory-side bonding pads 988C.

In one embodiment, the memory die 900 further comprises additional second-type memory-side bonding pads 988B electrically connected to source connection via structures 486 which electrically connect backside contact pad structures 488 to the source layer 110 through the logic die 700.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising a memory die, wherein the memory die comprises:
a source layer;
an alternating stack of insulating layers and electrically conductive layers;
memory openings vertically extending through the alternating stack;
memory opening fill structures located in the memory openings, wherein each of the memory opening fill structures comprises a respective vertical semiconductor channel, a respective vertical stack of memory elements located at levels of the electrically conductive layers, and a respective drain region contacting a first end of the respective vertical semiconductor channel, wherein a second end of the respective vertical semiconductor channel is electrically connected to the source layer, and wherein the electrically conductive layers comprise word lines of the respective vertical stack of memory elements;
bit lines electrically connected to a respective subset of the drain regions; and
memory-side dielectric material layers embedding memory-side metal interconnect structures and memory-side bonding pads, wherein the memory-side bonding pads comprise:
first-type memory-side bonding pads electrically connected to a respective one of the word lines or the bit lines; and
second-type memory-side bonding pads electrically connected to the source layer, wherein each of the first-type memory-side bonding pads has a first bonding surface area, and each of the second-type memory-side bonding pads has a second bonding surface area that is larger than the first bonding surface area.

2. The semiconductor structure of claim 1, wherein:
the memory-side bonding pads further comprise third-type memory-side bonding pads that are electrically isolated from the memory-side metal interconnect structures; and
each of the third-type memory-side bonding pads has a third bonding surface area that is smaller than the first bonding surface area.

3. The semiconductor structure of claim 2, wherein:
the second bonding surface area is at least 120% of the first bonding surface area; and
the third bonding surface area is 80% or less of the firs bonding surface area.

4. The semiconductor structure of claim 2, wherein the first-type memory-side bonding pads, the second-type memory-side bonding pads, and the third-type memory-side bonding pads have a same thickness and have a same material composition.

5. The semiconductor structure of claim 2, wherein:
a subset of the first-type memory-side bonding pads comprises a plurality of rows of first-type memory-side bonding pads arranged along a horizontal direction;
a subset of the second-type memory-side bonding pads comprises a plurality of rows of second-type memory-side bonding pads arranged along the horizontal direction;
a first subset of the third-type memory-side bonding pads is located between a pair of rows of first-type memory-side bonding pads; and
a second subset of the third-type memory-side bonding pads is located between a pair of rows of second-type memory-side bonding pads.

6. The semiconductor structure of claim 2, further comprising a logic die comprising:
a peripheral circuit including a source line driver, word line drivers, and bit line drivers; and
logic-side dielectric material layers embedding logic-side metal interconnect structures and logic-side bonding pads that are bonded to the memory-side bonding pads.

7. The semiconductor structure of claim 6, wherein the logic-side bonding pads comprise:
first-type logic-side bonding pads that are bonded to the first-type memory-side bonding pads;
second-type logic-side bonding pads that are bonded to the second-type memory-side bonding pads and that have a larger bonding surface area than the first-type logic-side bonding pads; and
third-type logic-side bonding pads that are bonded to the third-type memory-side bonding pads and that have a smaller bonding surface area than the first-type logic-side bonding pads.

8. The semiconductor structure of claim 7, wherein the third-type logic-side bonding pads are electrically isolated from the logic-side metal interconnect structures, and each bonded pair of a third-type memory-side bonding pad and a third-type logic-side bonding pad is electrically floating.

9. The semiconductor structure of claim 7, wherein:
the first-type logic-side bonding pads are electrically connected to a respective one of the word line drivers or the bit line drivers through a respective first subset of the logic-side metal interconnect structures; and
the second-type logic-side bonding pads are electrically connected to the source line driver through a second subset of the logic-side metal interconnect structures.

10. The semiconductor structure of claim 2, wherein:
each of the first-type memory-side bonding pads has a first width between a respective pair of parallel sidewalls thereof;
each of the second-type memory-side bonding pads has a second width between a respective pair of parallel sidewalls thereof; and
the second width is greater than the first width.

11. The semiconductor structure of claim 10, wherein:
each of the third-type memory-side bonding pads has a third width between a respective pair of parallel sidewalls thereof; and
the third width is less than the first width.

12. The semiconductor structure of claim 6, wherein:
the memory-side bonding pads further comprise in-chip monitor bonding pads that are electrically connected to a respective electrical node within the memory die through a respective subset of the memory-side metal interconnect structures;
each of the in-chip monitor bonding pads has a fourth bonding surface area that equals the second bonding surface area; and
a subset of the logic-side bonding pads is bonded to the in-chip monitor bonding pads and does not contact any of the logic-side metal interconnect structures.

13. The semiconductor structure of claim 6, wherein:
the memory die further comprises a memory-side edge-seal ring structure laterally surrounding an entirety of the memory-side metal interconnect structures and comprising a ring-shaped memory-side bonding pad located at a same level as the memory-side bonding pads;
the logic die further comprises a logic-side edge-seal ring structure laterally surrounding an entirety of the logic-side metal interconnect structures and comprising a ring-shaped logic-side bonding pad located at a same level as the logic-side bonding pads and bonded to the ring-shaped memory-side bonding pad;
a subset of the third-type memory-side bonding pads is located outside the ring-shaped memory-side bonding structure; and
another subset of the logic-side bonding pads is bonded to the subset of the third-type memory-side bonding pads.

14. The semiconductor structure of claim 1, wherein the memory die further comprises additional second-type memory-side bonding pads electrically connected to source connection via structures which electrically connect backside contact pad structures to the source layer through the logic die.

15. The semiconductor structure of claim 1, wherein the memory-side bonding pads comprise copper bonding pads.

16. A method of forming a semiconductor structure, comprising
providing a memory die comprising an alternating stack of insulating layers and electrically conductive layers, memory openings vertically extending through the alternating stack, memory opening fill structures located in the memory openings, wherein each of the memory opening fill structures comprises a respective vertical semiconductor channel, a respective vertical stack of memory elements located at levels of the electrically conductive layers, a respective drain region contacting a first end of the respective vertical semiconductor channel, a source layer electrically connected to second ends of a respective subset of the vertical semiconductor channels, wherein the electrically conductive layers comprise word lines of the respective vertical stack of memory elements, bit lines electrically connected to a respective subset of the drain regions, memory-side dielectric material layers embedding memory-side metal interconnect structures and memory-side bonding pads, wherein the memory-side bonding pads comprise first-type memory-side bonding pads electrically connected to a respective one of the word lines or the bit lines, and second-type memory-side bonding pads electrically connected to the source layer, wherein each of the first-type memory-side bonding pads has a first bonding surface area, and each of the second-type memory-side bonding pads has a second bonding surface area that is larger than the first bonding surface area;
plasma treating the memory side bonding pads;
chemically cleaning the memory side bonding pads; and
bonding the memory die to a logic die.

17. The method of claim 16, wherein:
the memory-side bonding pads further comprise third-type memory-side bonding pads that are electrically isolated from the memory-side metal interconnect structures; and
each of the third-type memory-side bonding pads has a third bonding surface area that is smaller than the first bonding surface area.

18. The method of claim 17, wherein:
the logic die comprises a peripheral circuit including a source line driver, word line drivers, and bit line drivers, and logic-side dielectric material layers embedding logic-side metal interconnect structures and logic-side bonding pads; and
the logic-side bonding pads are bonded to the memory-side bonding pads via copper-to-copper bonding.

19. The method of claim 18, wherein the logic-side bonding pads comprise:
first-type logic-side bonding pads that are bonded to the first-type memory-side bonding pads;
second-type logic-side bonding pads that are bonded to the second-type memory-side bonding pads; and
third-type logic-side bonding pads that are bonded to the third-type memory-side bonding pads.

20. The method of claim 17, wherein:
the memory-side bonding pads further comprise in-chip monitor bonding pads that are electrically connected to a respective electrical node within the memory die through a respective subset of the memory-side metal interconnect structures, and additional second-type memory-side bonding pads electrically connected to source connection via structures which electrically connect backside contact pad structures to the source layer through the logic die; and
each of the in-chip monitor bonding pads and the additional second-type memory-side bonding pads has a fourth bonding surface area that equals the second bonding surface area.
